(19) United States
(12) Patent Application Publication
(10) Pub. No.: US 2026/0013226 A1
(43) Pub. Date: Jan. 8, 2026

(54) DISPLAY PANEL HAVING MIXED TRANSISTORS AND METHOD OF MANUFACTURING THE SAME

(71) Applicant: SAMSUNG DISPLAY CO., LTD., Yongin-si (KR)

(72) Inventors: SANGWOO SOHN, Yongin-si (KR); Kyung-Tae KIM, Yongin-si (KR); YEON KEON MOON, Yongin-si (KR); JUN HYUNG LIM, Yongin-si (KR); Hyunjun JEONG, Yongin-si (KR); Hyoung Do KIM, Yongin-si (KR); HYELIM CHOI, Yongin-si (KR)

(21) Appl. No.: 19/258,534

(22) Filed: Jul. 2, 2025

(30) Foreign Application Priority Data
Jul. 5, 2024 (KR) 10-2024-0088806

(51) Int. Cl. H10D 86/40; H10D 86/01; H10D 86/60; H10K 59/12; H10K 59/121

(52) U.S. Cl. CPC H10D 86/425; H10D 86/0223; H10D 86/0231; H10D 86/423; H10D 86/481; H10D 86/60; H10K 59/1201; H10K 59/1213

(57) ABSTRACT

A display device includes plurality of light-emitting elements. A plurality of pixel drivers are respectively connected to the light-emitting elements. Each of the plurality of pixel drivers includes a first transistor including a first oxide semiconductor pattern, a second transistor electrically connected to the first transistor and including a second oxide semiconductor pattern, and a capacitor electrically connected to a gate of the first transistor. The first oxide semiconductor pattern has a crystalline structure and the second oxide semiconductor pattern has an amorphous structure.

### CROSS-REFERENCE TO RELATED APPLICATIONS

This U.S. non-provisional patent application claims priority under 35 U.S.C. § 119 to Korean Patent Application No. 10-2024-0088806, filed on Jul. 5, 2024, the entire contents of which are hereby incorporated by reference.

### TECHNICAL FIELD

The present disclosure herein relates to a display panel and, more particularly, to a display panel having transistors of mixed types and a method of manufacturing the same.

### DISCUSSION OF THE RELATED ART

A display panel may include a plurality of pixels for displaying an image. These pixels may include light-emitting elements, such as for an organic light-emitting diode (OLED) display device. For each pixel, a driver may control the light-emitting element. The pixel drivers may each include a switching transistor for controlling when a pixel is active and inactive and a driving transistor for controlling the pixel brightness, which may be referred to as the grayscale value.

### SUMMARY

A display panel includes a substrate. A plurality of light-emitting elements are disposed on the substrate. A plurality of pixel drivers are respectively electrically connected to the light-emitting elements. Each of the plurality of pixel drivers includes a first transistor including a first oxide semiconductor pattern, a second transistor electrically connected to the first transistor and including a second oxide semiconductor pattern, and a capacitor electrically connected to a gate of the first transistor. The first oxide semiconductor pattern has a crystalline structure and the second oxide semiconductor pattern has an amorphous structure.

The first transistor may be a driving transistor and the second transistor may be a switching transistor.

The first oxide semiconductor pattern may include at least one of indium, gallium, or zinc.

The second oxide semiconductor pattern may include at least one of indium, tin, gallium, or zinc.

The second oxide semiconductor pattern may include indium, tin, gallium and zinc, and a composition ratio in the second semiconductor pattern may be about 60 to about 80 wt % of indium, about 0.5 to about 8 wt % of tin, about 5 to about 15 wt % of gallium, and about 10 to about 30 wt % of zinc.

The first oxide semiconductor pattern and the second oxide semiconductor pattern may be disposed on the same layer.

The display panel may further include a lower conductive layer disposed between the first transistor and the substrate. A buffer layer may be disposed between the lower conductive layer and the first oxide semiconductor pattern. The first oxide semiconductor pattern and the second oxide semiconductor pattern may be disposed on the buffer layer.

A source of the first transistor may be electrically connected to the lower conductive layer.

Each of the first transistor and the second transistor may have a top-gate structure.

An electronic device, such as a display device, includes a display panel and an input sensor. The display panel includes a substrate, a light-emitting element disposed on the substrate, a driving transistor disposed on the substrate and electrically connected to the light-emitting element, and a plurality of switching transistors electrically connected to the driving transistor and the light-emitting element. The driving transistor includes a first oxide semiconductor pattern with a crystalline structure. Each of the switching transistors may include a second oxide semiconductor pattern with an amorphous structure.

Each of the driving transistor and the switching transistors may have a top-gate structure.

The first oxide semiconductor pattern and the second oxide semiconductor pattern may be disposed on the same layer.

A source electrode and a drain electrode of each of the driving transistor and switching transistors may be disposed on the same layer.

The electronic device may further include a buffer layer disposed between the substrate and the driving transistor, and a lower conductive layer disposed between the buffer layer and the substrate and overlapping the first oxide semiconductor pattern in a plan view. A source of the driving transistor may contact the lower conductive layer.

The first oxide semiconductor pattern may have a charge mobility of about 30 cm²/v·s or higher.

The second oxide semiconductor pattern may have a driving range of about 0.4 V or higher.

A method for manufacturing a display panel includes disposing a first thin-film transistor on a substrate. The first thin-film transistor includes a first semiconductor pattern. A second thin-film transistor is disposed on the substrate. The second thin-film transistor includes a second semiconductor pattern that is spaced apart from the first semiconductor pattern. A light-emitting element is disposed on the substrate. The providing of the first thin-film transistor includes providing a first semiconductor layer with a first oxide semiconductor material, patterning the first semiconductor layer to provide the first semiconductor pattern, and crystallizing the first semiconductor pattern. The providing of the second thin-film transistor includes providing a second semiconductor layer with a second semiconductor material on the first semiconductor pattern, and patterning the second semiconductor layer to provide the second semiconductor pattern. The second semiconductor pattern has an amorphous structure.

The second semiconductor layer may contact the first semiconductor pattern.

The patterning of the second semiconductor layer may include using an enchant to etch the second semiconductor layer, and the first semiconductor pattern may be exposed to the enchant.

A source, a drain and a channel of each of the first semiconductor pattern and the second semiconductor pattern may be provided substantially simultaneously.

### BRIEF DESCRIPTION OF THE FIGURES

A more complete appreciation of the present disclosure and many of the attendant aspects thereof will be readily obtained as the same becomes better understood by reference to the following detailed description when considered in connection with the accompanying drawings, wherein:

FIG. 1 is a perspective view of a display device according to an embodiment of the inventive concept;

FIG. 2 is a cross section of the display device shown in FIG. 1;

FIG. 3 is a cross section of the display panel shown in FIG. 2.

FIG. 4 is a block diagram of the display device shown in FIG. 1;

FIGS. 5A, 5B, and 5C are equivalent circuit diagrams of a pixel according to an embodiment of the inventive concept;

FIG. 6 is a timing diagram of scan signals and emission signals for describing an operation of the pixel shown in FIG. 5A;

FIGS. 7A, 7B, 7C, and 7D are cross-sections of partial areas of a display panel;

FIGS. 8A and 8B are graphs of the current-voltage characteristics of a semiconductor pattern according to an embodiment of the inventive concept;

FIGS. 9A, 9B, 9C, 9D, 9E, 9F, 9G, 9H, 9I, 9J, 9K, 9L, and 9M are cross-sectional views showing a method of manufacturing a display panel according to an embodiment of the inventive concept;

FIG. 10 is a block diagram of an electronic device EA according to an embodiment of the inventive concept; and

FIG. 11 is a schematic diagrams of an electronic device according to various embodiments.

### DETAILED DESCRIPTION

In describing embodiments of the present disclosure illustrated in the drawings, specific terminology is employed for sake of clarity. However, the present disclosure is not necessarily intended to be limited to the specific terminology so selected, and it is to be understood that each specific element includes all technical equivalents which operate in a similar manner.

It will be understood that when an element or layer is referred to as being “on”, “connected to” or “coupled to” another element or layer, it can be directly on, connected or coupled to the other element or intervening third elements may be present.

Like reference numerals in the drawings and specification may refer to like elements. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

The term “and/or” includes any and all combinations of one or more of the associated items.

Terms such as first, second and the like may be used to describe various components, but these components should not necessarily be limited by the terms. Such terms are used for distinguishing one element from other elements. For instance, a first component may be referred to as a second component, or similarly, a second component may be referred to as a first component, without departing from the scope of the present disclosure. The singular expressions include plural expressions unless the context clearly dictates otherwise.

In addition, the terms such as “under”, “lower”, “on”, and “upper” are used for explaining associations of items illustrated in the drawings. The terms are used as a relative concept and are described with reference to the direction indicated in the drawings.

It will be further understood that the terms “comprises,” “comprising,” “includes” and/or “including”, when used in this specification, specify the presence of stated features, integers, steps, operations, elements, components or combinations thereof, but do not necessarily preclude the presence or addition of one or more other features, integers, steps, operations, elements, components, or combinations thereof.

Embodiments of the present inventive concept relate to a display device, an electronic device including the device, and a method for manufacturing the display device in which a plurality of pixels each include at least a driving transistor and a switching transistor. The driving transistor uses a crystalline oxide semiconductor that provides a wide driving range and better handling of grayscale representation. The switching transistor uses an amorphous oxide semiconductor, which offers high mobility for faster switching and improved on-off characteristics.

The particular crystalline oxide semiconductor used may be, for example, indium, gallium, and/or zinc. The amorphous oxide semiconductor may also be, for example, indium, gallium, and/or zinc but it is not necessarily required that the crystalline oxide semiconductor be the same material as the amorphous oxide semiconductor, other than the difference in atomic organization (e.g., amorphous or crystalline).

According to this approach, the sequential fabrication of crystalline and amorphous transistors on the same substrate layer may enable simpler processing. During fabrication, a crystallization process may be applied only to the driving transistor area, leaving switching transistors in their amorphous state. Thus, at the point of deposition, both transistors may have the oxide semiconductor disposed in its amorphous state.

By utilizing this method and/or structure, grayscale performance is enhanced through a wider voltage control range, leakage current is reduced and faster switching for high-resolution displays is achieved. Moreover, long-term reliability of the driving transistors is improved.

Hereinafter, embodiments of the inventive concept will be described with reference to the accompanying drawings.

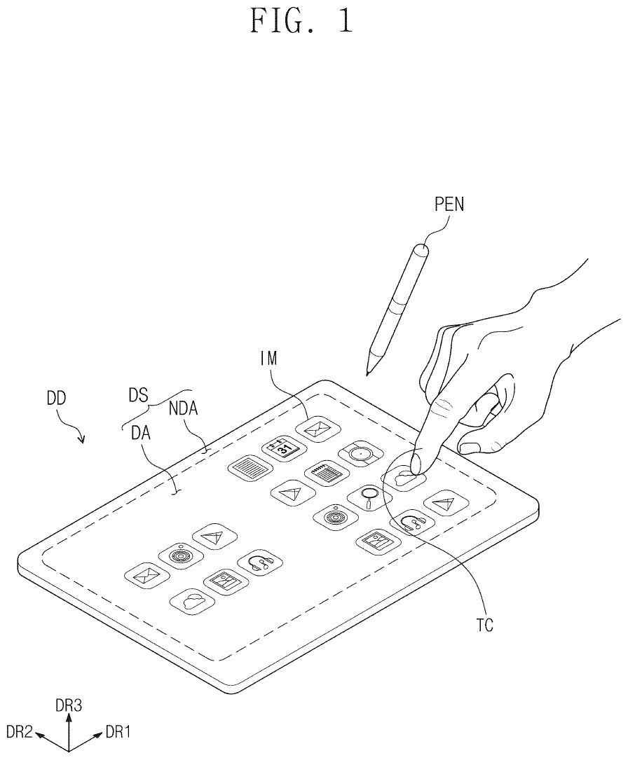

FIG. 1 is a perspective view of an electronic device according to an embodiment of the inventive concept. As shown in FIG. 1, the electronic device DD may have a pair of long sides extending in a first direction DR1 and a pair of short sides extending in a second direction DR2 intersecting with the first direction DR1.

Hereinafter, a direction substantially vertically crossing a plane defined by the first and second directions DR1 and DR2 is defined as a third direction DR3. In addition, in the present specification, the expression “when viewed in a plan view” is defined as a state viewed in the third direction DR3.

The front surface of the electronic device DD may be defined as a display surface DS, and have a plane defined by the first direction DR1 and the second direction DR2. Images IM generated in the electronic device DD may be provided to the user via the display surface DS.

The display surface DS may include a display area DA and a non-display area NDA proximate to and/or at least partially surrounding the display area DA. The display area DA may be defined as an area in which the images are displayed, and the non-display area NDA may be defined as an area in which the images are not displayed. The non-display area NDA may be adjacent to at least one side of the display area DA. In the embodiment, the non-active area NDA may have a frame shape surrounding the display area DA.

The electronic device DD may also be configured to detect external inputs applied to the electronic device DD. For example, the electronic device DD may detect a first input via a stylus PEN and a second input from touches TC. Here, the stylus PEN may be defined as an input device, and in addition to displaying the images, the display area DA may provide a user with a detection area in which an input may be detected.

The stylus PEN may be an active stylus/pen, an electromagnetic stylus/pen or the like. The second input from touches TC may include various types of external inputs including a touch from a part of the user's body, light, heat, pressure or the like. The stylus PEN may include an active stylus/pen, a passive stylus/pen, an electromagnetic stylus/pen or the like, and is not necessarily limited to any one embodiment.

The electronic device DD may be used in a large-scale electronic device such as a television, a computer monitor, and an outdoor digital billboard. In addition, the electronic device DD may be used in a small or medium-sized electronic device such as a laptop/notebook computer, a personal digital assistant, a vehicle navigation device, a portable game console, a smartphone, a tablet computer, or a digital camera, etc. However, these are illustrative and the present invention is not necessarily limited to any one embodiment. The electronic device DD, according to an embodiment of the inventive concept, may be used in various types of devices and is not necessarily limited to any one embodiment.

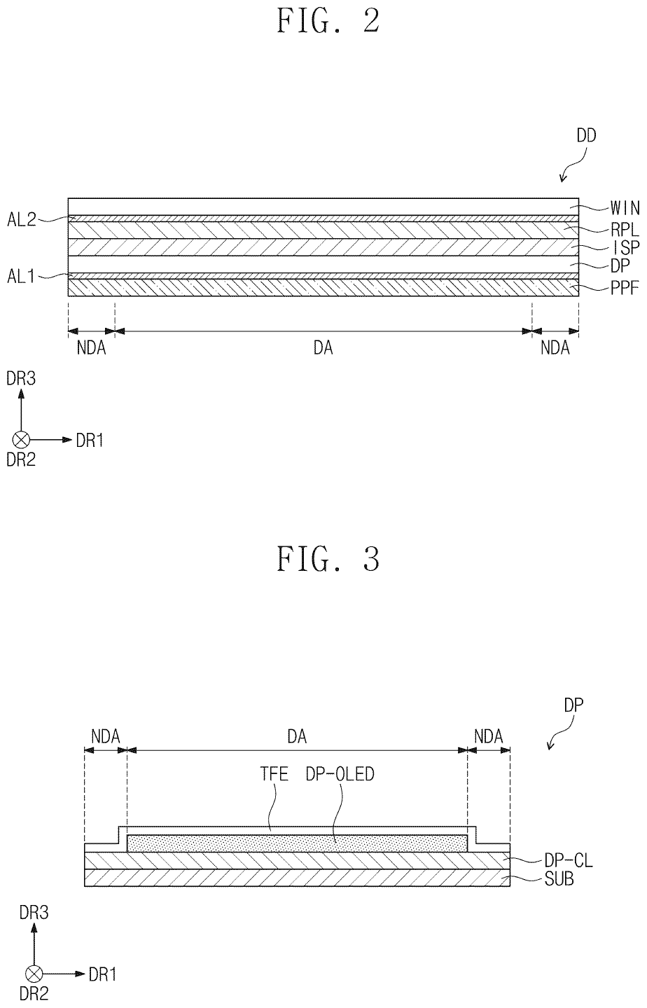

FIG. 2 illustrates an example cross section of the display device shown in FIG. 1. FIG. 3 illustrates an example cross section of the display panel shown in FIG. 2. Hereinafter, the inventive concept will be described with reference to FIGS. 2 and 3.

Referring to FIG. 2, the electronic device DD includes a display panel DP, an input sensor ISP, an anti-reflection layer RPL, a window WIN, a panel protection film PPF, and first and second adhesive layers AL1 and AL2.

The display panel DP, according to an embodiment of the inventive concept, may be an emissive display panel. For example, the display panel DP may be an organic light emitting diode (OLED) display panel or an inorganic light-emitting display panel. An emission layer of the organic light-emitting display panel may include an organic light-emitting material. An emission layer of the inorganic light-emitting display panel may include quantum dots, quantum rods or the like. Hereinafter, the display panel DP will be described as an organic light-emitting display panel.

Referring to FIG. 3, the display panel DP may include a substrate SUB, a circuit element layer DP-CL disposed on the substrate SUB, a display element layer DP-OLED disposed on the circuit element layer DL-CL, and a thin-film encapsulation layer TFE disposed on the display element layer DP-OLED.

The substrate SUB may include the display area DA and the non-display area NDA proximate to the display area DA. The substrate SUB may include glass or a flexible plastic material such as polyimide (PI). The display element layer DP-OLED may be disposed on the display area DA.

A plurality of pixels may be arranged in the circuit element layer DP-CL and the display element layer DP-OLED. Each of the pixels may include transistors disposed in the circuit element layer DP-CL and a light emitting element disposed in the display element layer DP-OLED and connected to the transistors.

The thin film encapsulation layer TFE may be disposed on the circuit element layer DP-CL to cover the display element layer DP-OLED. The thin film encapsulation layer TFE may protect the pixels from moisture, oxygen, and foreign matters. The thin film encapsulation layer TFE is shown as covering the overall area of the substrate SUB, but according to an embodiment of the inventive concept, the substrate SUB may also include a partial area exposed from the thin film encapsulation layer TFE. Alternatively, an area exposed from the thin film encapsulation layer TFE may be provided along the edge of the substrate SUB and is not necessarily limited to any one embodiment.

The input sensor ISP may be arranged on the display panel DP. The input sensor ISP may include a plurality of sensors configured to sense external inputs in an electrostatic capacitive manner. When manufacturing the electronic device DD, the input sensor ISP may be manufactured directly on the display panel DP. For example, a conductive pattern or an insulation layer composing the input sensor ISP may be directly deposited or patterned on the display panel DP. However, the embodiment is not necessarily limited thereto. The input sensor ISP may be manufactured as a separate panel from the display panel DP and may be adhered to the display panel DP via an adhesive layer, and is not necessarily limited to any one embodiment.

The anti-reflection layer RPL may be disposed on the input sensor ISP. The anti-reflection layer RPL may reduce the external light reflectance of the electronic device DD to increase the visibility of an image displayed on the electronic device DD. The anti-reflection layer RPL may include a phase retarder, a polarizer, a black matrix, a color filter, or the like, and is not necessarily limited to any one embodiment. The anti-reflection layer RPL may be directly provided on the input sensor ISP through coating or deposition processes, or be provided as a film to be adhered to the input sensor ISP via an adhesive layer, and is not necessarily limited to any one embodiment.

The window WIN may be disposed on the anti-reflection layer RPL. The window WIN may protect the display panel DP, the input sensor ISP, and the anti-reflection layer RPL from an external scratch or shock.

The panel protection film PPF may be disposed under the display panel DP. The panel protection film PPF may support the display panel DP and protect the bottom side of the display panel DP. The panel protection film PPF may have insulating properties. For example, the panel protection film PPF may include plastics such as polyethyleneterephthalate (PET), polyimide, (PI), or polypropylene (PP), but is not necessarily limited thereto.

The first adhesive layer AL1 may be disposed between the display panel DP and the panel protection film PPF, and the display panel DP and the panel protection film PPF may adhere to each other by means of the first adhesive layer AL1. The second adhesive layer AL2 may be disposed between the window WIN and the anti-reflection layer RPL, and the window WIN and the reflection protection layer RPL may adhere to each other by means of the second adhesive layer AL2.

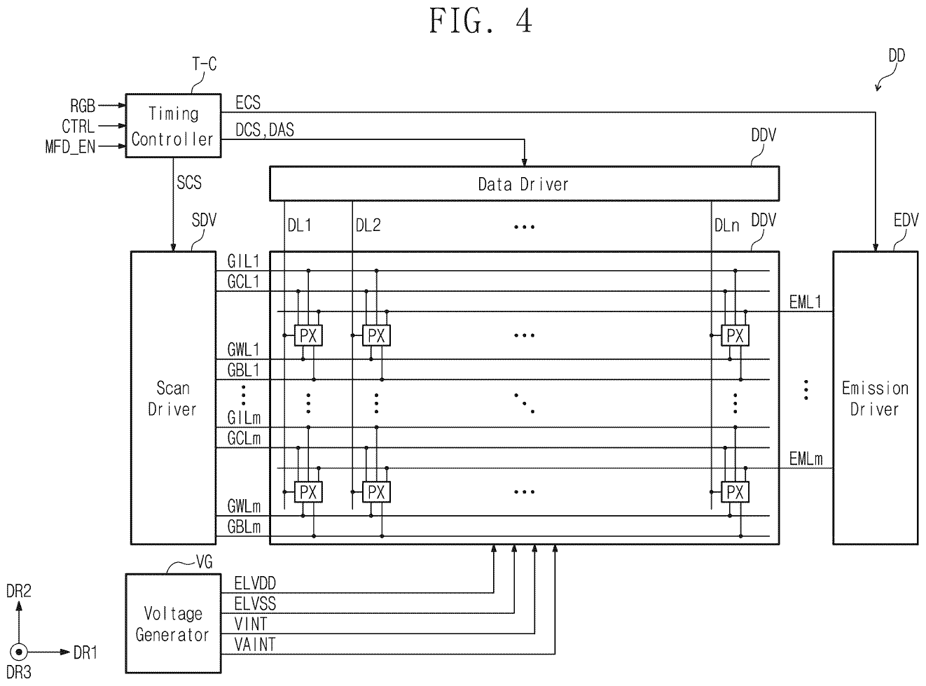

FIG. 4 is a block diagram of the display device shown in FIG. 1. Referring to FIG. 4, the electronic device DD may include a timing controller T-C, a scan driver SDV, a data driver DDV, an emission driver EDV, and a voltage generator VG.

The display panel DP may include a plurality of scan lines GIL1 to GILm, GCL1 to GCLm, GWL1 to GWLm, and GBL1 to GBLm, a plurality of emission lines EML1 to EMLm, a plurality of data lines DL1 to DLm, and a plurality of pixels PX. Here, m and n are positive integers.

The plurality of pixels PX may be respectively electrically connected to the scan lines GIL1 to GILm, GCL1 to GCLm, GWL1 to GWLm, and GBL1 to GBLm, the emission lines EML1 to EMLm, and the data lines DL1 to DLm. Each of the pixels PX may be electrically connected to four corresponding scan lines, one corresponding data line, and one corresponding emission line.

The scan lines GIL1 to GILm, GCL1 to GCLm, GWL1 to GWLm, and GBL1 to GBLm may include the plurality of initialization scan lines GIL1 to GILm, the plurality of compensation scan lines GCL1 to GCLm, the plurality of write scan lines GWL1 to GWLm, and the plurality of bias scan lines GBL1 to GBLm.

Each of the pixels PX may be connected to a corresponding one of the initialization scan lines GIL1 to GILm, a corresponding one of the compensation scan lines GCL1 to GCLm, a corresponding one of the write scan lines GWL1 to GWLm, and a corresponding one of the bias scan lines GBL1 to GBLm.

The scan lines GIL1 to GILm, GCL1 to GCLm, GWL1 to GWLm, and GBL1 to GBLm may be connected to the scan driver SDV and extend in the first direction DR1 to be arranged in the second direction DR2. The emission line EML1 to EMLm may be connected to the emission driver EDV and extend in the first direction DR1 to be arranged in the second direction DR2. The data lines DL1 to DLn may be connected to the data driver DDV and extend in the second direction DR2 to be arranged in the first direction DR1.

In the embodiment, the scan driver SDV, the emission driver EDV and the data driver DDV may be substantially arranged in the display panel DP. However, this is illustrative and is not necessarily limited to any one embodiment. At least one of the scan driver SDV, the emission driver EDV and the data driver may be provided in a separate circuit board and be electrically connected to the display panel DP to provide electrical signals to the pixels PX.

The timing controller T-C may receive an image signal RGB and a control signal CTRL. The timing controller T-C may generate an image data signal DAS of which data format is converted from the image signal RGB so as to be matched with the specification of an interface with the data driver DDV. The timing controller T-C may output a scan control signal SCS, a data control signal DCS, and an emission control signal ECS in response to a control signal CTRL.

The voltage generator VG may generate voltages required for the operation of the display panel DP. The voltage generator VG generates a first driving voltage ELVDD, a second driving voltage ELVSS, a first initialization voltage VINT, and a second initialization voltage VAINT. The first driving voltage ELVDD, the second driving voltage ELVSS, the first initialization voltage VINT, and the second initialization voltage VAINT may be applied to the pixels PX.

The scan driver SDV may receive the scan control signal SCS from the timing controller T-C. In response to the scan control signal SCS, the scan driver SDV may output the scan signals to the scan lines GIL1 to GILm, GCL1 to GCLm, GWL1 to GWLm, and GBL1 to GBLm. The scan signals may be applied to the pixels PX via the scan lines GIL1 to GILm, GCL1 to GCLm, GWL1 to GWLm, and GBL1 to GBLm.

The data driver DDV may receive the data control signal DCS and the image data signal DAS from the timing controller T-C. The data driver DDV may convert the image data signal DAS into data signals to be output. The data signals may be defined as analog voltages corresponding to the grayscale levels of the image data signal DAS. The data signals may be applied to the pixels via the data lines DL1 to DLn.

The emission driver EDV may receive the emission control signal ECS from the timing controller T-C. In response to the emission control signal ECS, the emission driver EDV may output the emission signals to the emission control lines EML1 to EMLn. The emission signals may be applied to the pixels PX via the emission lines EML1 to ELm.

The pixels PX may receive data voltages in response to the scan signals. In response to the emission signals, the pixels PX may display an image by emitting light of the luminance corresponding to the data voltages.

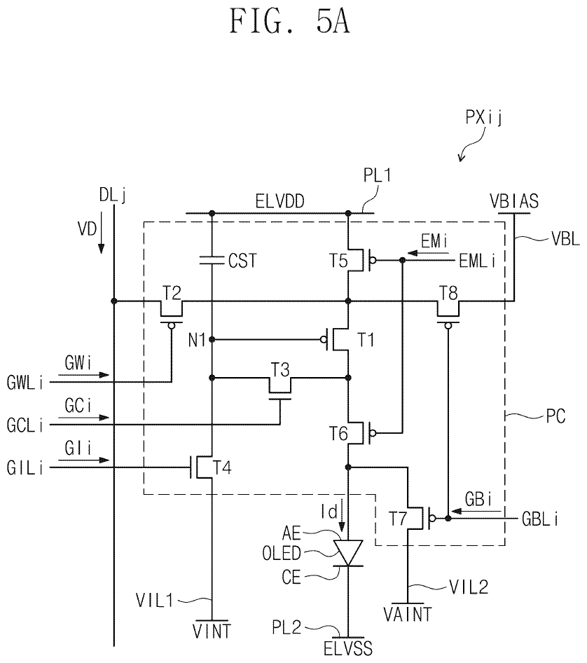

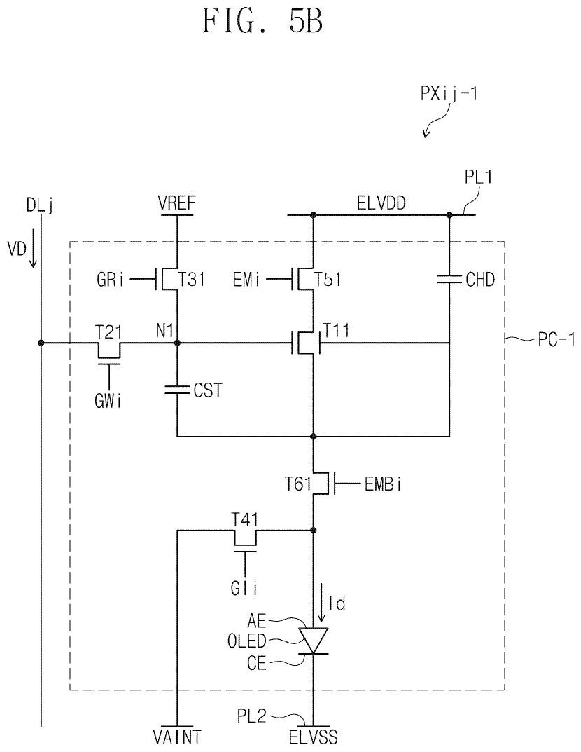

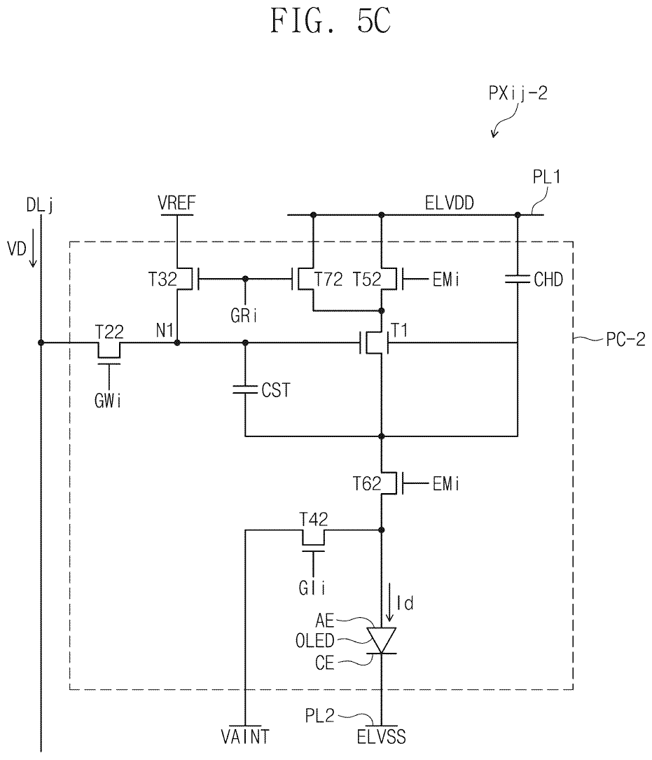

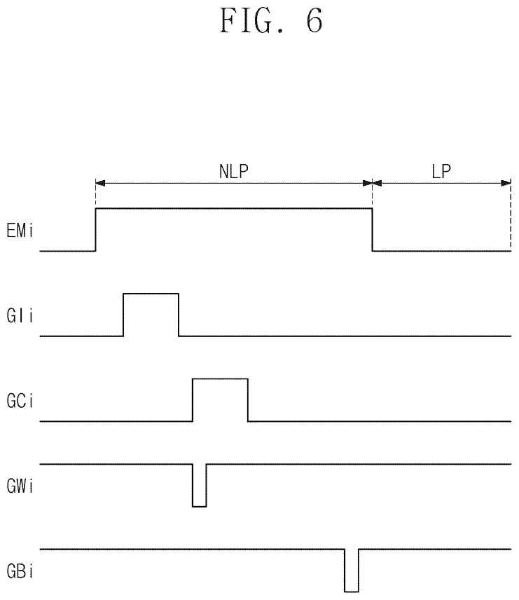

FIGS. 5A to 5C illustrate equivalent circuits of any one pixel among the pixels shown in FIG. 4. FIG. 6 is a timing diagram of scan signals and emission signals for describing the operation of the pixel according to an embodiment of the inventive concept. FIG. 6 shows an example timing diagram of the pixel shown in FIG. 5A. Hereinafter, the pixel will be described in detail with reference to FIGS. 5A to 6.

By way of example, FIG. 5A illustrates a pixel PXij connected to a j-th data line DLj, i-th scan lines GWLi, GCLi, GILi and GBLi, and an i-th emission line EMLi. Here, i and j are positive integers.

Referring FIG. 5, the pixel PXij may include a pixel driver PC and a light-emitting element OLED electrically connected to the pixel driver PC. The pixel driver PC may drive the light-emitting element OLED.

The pixel driver PC may include a plurality of transistors T1 to T8 and a capacitor CST. The transistors T1 to T8 and the capacitor CST may control an amount of a current flowing through the light-emitting element OLED. The light-emitting element OLED may generate light of prescribed luminance corresponding to the received current amount.

An i-th write scan line GWLi may receive an i-th write scan signal GWi, and the i-th compensation scan line GCLi may receive the i-th compensation scan signal GCi. The i-th initialization scan line GILi may receive an i-th initialization scan signal GWi, and the i-th bias scan line GBLi may receive the i-th bias scan signal GBi. The i-th emission line EMLi may receive the i-th emission signal EMi.

The pixel PXij may be connected to the j-th data line DLj, the i-th write scan line GWLi, the i-th compensation scan line GCLi, the i-th initialization scan line GILi, the i-th bias scan line GBLi, the i-th emission line EMLi, a first initialization line VIL1, a second initialization line VIl2, the bias line VBL, and the first and second power lines PL1 and PL2.

The first initialization line VIL1 may receive the first initialization voltage VINT and the second initialization line VIL2 may receive the second initialization voltage VAINT. The bias line VBL may receive the bias voltage VBIAS. The first power line PL1 may receive the first driving voltage ELVDD and the second power line may receive the second driving voltage ELVSS.

The transistors T1 to T8 each may include a source electrode, a drain electrode, and a gate electrode. Hereinafter, for convenience, any one of the source and drain electrodes in FIGS. 5A to 5C may be defined as a first electrode and the other may be defined as a second electrode. In addition, the gate electrode may be defined as a control electrode.

The transistors T1 to T8 may include first to eighth transistors T1 to T8. The first, second, fifth to eight transistors T1, T2, T5 to T8 may be P-type metal-oxide-semiconductor (PMOS) transistors. The third and fourth transistors T3 and T4 may be N-type metal-oxide-semiconductor (NMOS) transistors.

The first transistor T1 may be defined as a driving transistor, and the second transistor T2 may be defined as a switching transistor. The third transistor T3 may be defined as a compensation transistor. The fourth and seventh transistors T4 and T7 may be defined as initialization transistors. The fifth and sixth transistors T5 and T6 may be defined as emission control transistors. The eighth transistor T8 may be defined as a bias transistor.

The light-emitting element OLED may be defined as an organic light-emitting element. The light-emitting element OLED may include an anode AE and a cathode CE. The anode AE may receive the first driving voltage ELVDD from the sixth, first and fifth transistors T6, T1, and T5. The first driving voltage ELVDD may be applied to the pixel driver PC via the first power line PL1.

The cathode CE may receive the second driving voltage ELVSS having a lower level than the first driving voltage ELVDD. The second driving voltage ELVSS may be applied to the pixel driver PC via the second power line PL2.

The first transistor T1 may be disposed between the fifth transistor T5 and the sixth transistor T6 and may be connected to the fifth and sixth transistors T5 and T6. The first transistor T1 may be connected to the first power line PL1 via the fifth transistor T5 and connected to the anode AE via the sixth transistor T6.

The first transistor T1 may include a first electrode connected to the first power line PL1 via the fifth transistor T5, a second electrode connected to the anode AE via the sixth transistor T6, and a control electrode connected to a first node N1.

A first electrode of the first transistor T1 may be connected to the fifth transistor T5, and a second electrode of the first transistor T1 may be connected to the sixth transistor T6. The first transistor T1 may control the amount of a current flowing through the organic light-emitting element OLED according to a voltage of the first node N1 applied to the control electrode of the first transistor T1.

The second transistor T2 may be disposed between the fifth transistor T1 and the j-th data line DLj and may be connected to the fifth transistor T1 and the j-th data line DLj. The second transistor T2 may include a first electrode connected to the j-th data line DLj, a second electrode connected to the first electrode of the first transistor T1, and a control electrode connected to an i-th write scan line GWLi.

The second transistor T2 may be turned on by the i-th write scan signal GWi applied via the i-th write scan line GWLi to electrically connect the j-th data line DLj and the first electrode of the first transistor T1. The second transistor T2 may perform a switching operation for providing a data voltage Vd (corresponding to the data signal) applied via the j-th data line DLj to the first electrode of the first transistor T1.

The third transistor T3 may be connected between the second electrode of the first transistor T1 and the first node N1. The third transistor T3 may include a first electrode connected to the second electrode of the first transistor T1, a second electrode connected to the first node N1, and a control electrode connected to the i-th compensation scan line GCLi.

The third transistor T3 may be turned on by the i-th compensation scan signal GCi applied via the i-th write scan line GCLi to electrically connect the second electrode of the first transistor T1 and the control electrode of the first transistor T1. When the third transistor T3 is turned on, the first transistor T1 and the third transistor T3 may be connected in a diode type.

The fourth transistor T4 may be connected to the first node N1. The fourth transistor T4 may include a first electrode connected to the first node N1, a second electrode connected to the first initialization line VIL1, and a control electrode connected to the i-th initialization scan line GILi. The fourth transistor T4 may be turned on by the i-th initialization scan signal GIi applied via the i-th initialization scan line GILi to provide, to the first node N1, the first initialization voltage VINT applied via the first initialization line VIL1.

The fifth transistor T5 may include a first electrode connected to the first power line PL1, a second electrode connected to the first electrode of the first transistor T1, and a control electrode connected to the i-th emission line EMLi.

The sixth transistor T6 may include a first electrode connected to the second electrode of the first transistor T1, a second electrode connected to the anode AE, and a control electrode connected to the i-th emission line EMLi.

The fifth transistor T5 and the sixth transistor T6 may be turned on by the i-th emission signal EMi applied via the i-th emission line EMLi. The first voltage ELVDD may be provided to the light-emitting element OLED by the turned-on fifth and transistors T5 and T6 to cause the driving current to flow to the light-emitting element OLED. Accordingly, the light emitting element OLED may emit light.

The seventh transistor T7 may include a first electrode connected to the anode AE, a second electrode connected to the second initialization line VIL2, and a control electrode connected to the i-th bias scan line GBLi. The seventh transistor T7 may be turned on by the i-th bias scan signal GBi applied via the i-th bias scan line GBLi to provide, to the anode AE of the light-emitting element OLED, the second initialization voltage VAINT received via the second initialization line VIL2.

In an embodiment of the inventive concept, the second initialization voltage VAINT may have a different level from the first initialization voltage VINT, but is not necessarily limited thereto. The second initialization voltage VAINT may have the same level as the first initialization voltage VINT.

The seventh transistor T7 may increase the black level representation capability of the pixel PXij. When the seventh transistor T7 is turned on, a parasitic capacitor of the organic light emitting element OLED may be discharged. Accordingly, when the black luminance is implemented, the light-emitting element OLED might not emit light due to a leakage current of the first transistor T1, and thereby the black level representation capability may be increased.

The capacitor CST may include a first electrode connected to the first power line PL1 and a second electrode connected to the first node N1. When the fifth transistor T5 and the sixth transistor T6 are turned on, the amount of the current flowing through the first transistor T1 may be determined according to the voltage stored in the capacitor CST.

The eight transistor T8 may include a first electrode connected to the bias line VBL, a second electrode connected to the first electrode of the first transistor T1, and a control electrode connected to an i-th bias scan line GBLi.

The eight transistor T8 may be turned on by the i-th bias scan signal GBi to provide, to the first electrode of the first transistor T1, the bias voltage VBIAS applied via the bias line VBL.

Referring to FIGS. 5A and 6, the i-th emission signal EMi may have a high level in a non-emission period NLP and a low level in an emission period LP.

An activation period of each of the i-th write scan signal GWi and the i-th bias scan signal GBi may be defined as a low level of each of the i-th write scan signal GWi and the i-th bias scan signal GBi.

An activation period of each of the i-th compensation scan signal GCi and the i-th initialization scan signal GIi may be defined as a high level of each of the i-th compensation scan signal GCi and the i-th initialization scan signal GIi.

After the i-th initialization scan signal GIi is activated, the i-th compensation scan signal GCi and the i-th write scan signal GWi may be activated. Then the i-th bias scan signal GBi may be activated.

During the non-emission period NLP, the activated i-th initialization scan signal GIi, i-th compensation scan signal GCI, i-th write scan signal GWi, and i-th bias scan signal GBi may be applied to the pixel PXij.

The i-th initialization signal GIi may be applied to turn on the fourth transistor T4. The first initialization voltage VINT may be applied to the first node N1 via the fourth transistors T4. Accordingly, the first initialization voltage VINT may be applied to the control electrode of the first transistor T1 to initialize the first transistor T1. Such an operation may be defined as an initialization operation.

The i-th write scan signal GWi may be applied to turn on the second transistor T2. Furthermore, the i-th compensation scan signal GCi may be applied to turn on the third transistor T3.

The first and third transistors T1 and T3 may be connected to each other in a diode type. In this case, a compensation voltage (Vd-Vth), which results from subtracting a threshold voltage Vth of the first transistor T1 from the data voltage VD supplied via the data line DLj, may be applied to the control electrode of the first transistor T1. This operation may be defined as a write operation (or a programming operation) and a compensation operation.

The first voltage ELVDD and the compensation voltage Vd-Vth may be respectively applied to the first electrode and the second electrode of the capacitor CST. Charge corresponding to a voltage difference between first and second electrodes of the capacitor CST may be stored in the capacitor CST.

Then, the i-th bias scan signal GBi may be applied to the seventh and eight transistors T7 and T8 to turn on the seventh and eighth transistors T7 and T8. The second initialization voltage VAINT may be supplied to the anode AE via the seventh transistor T7 to initialize the anode AE to have the second initialization voltage VAINT. The bias voltage VBIAS may be applied to the first electrode of the first transistor T1 via the eighth transistor T8.

Then, during the emission period LP, the i-th emission signal EMi may be applied to the fifth and sixth transistors T5 and T6 via the i-th emission line ELi to turn on the fifth and sixth transistors T5 and T6. In this case, a driving current Id may be generated in correspondence to the difference between the first voltage ELVDD and the voltage of the control electrode of the first transistor T1. The driving voltage Id may be provided to the light-emitting element OLED via the sixth transistor T6 to cause the light-emitting element OLED to emit light.

During the emission period LP, a gate-source voltage Vgs of the first transistor T1 may be defined as Vgs=ELVDD−(Vd−Vth) by the capacitor CST. The current-voltage relationship of the first transistor T1 may be defined as Id=1/2 μCox (W/L)(Vgs−Vth)². Such an equation is the current-voltage relationship of a typical transistor.

When the gate-source voltage Vgs is substituted for the current-voltage relationship, the threshold voltage Vth is removed, and the driving current Id may be proportional to a square value (ELVDD−Vd)² of a value obtained by subtracting the data voltage Vd from the first voltage ELVDD. Accordingly, the driving current Id may be determined regardless of the threshold voltage Vth of the first transistor T1. Such an operation may be defined as a threshold voltage compensation operation.

The bias voltage VBIAS may be applied to the first electrode of the first transistor T1 via the eighth transistor T8 before emission of the light-emitting element OLED after the threshold voltage of the first transistor T1 has been compensated. The bias voltage VBIAS may suppress the movement of the hysteresis loop of the first transistor T1. Such an operation may be defined as a bias operation.

Referring to FIG. 5B, a pixel driver PC-1 may include six transistors T11, T21, T31, T41, T51 and T61 and two capacitors CST and CHD.

The first transistor T11 may be defined as a driving transistor, and the second transistor T21 may be defined as a switching transistor.

The third transistor T31 may be defined as a reset transistor. The third transistor T31 may provide a reference voltage VREF to the first node N1 in response to a reset signal GRi transferred from the scan driver SDV (see FIG. 4). The first node N1 may be reset by the reference voltage VREF to minimize the influence of a voltage remaining in the previous step.

The fourth transistor T41 may be an anode initialization transistor. The fourth transistor T41 may correspond to the seventh transistor T7 shown in FIG. 5A. The fourth transistor T41 may initialize the anode of the light-emitting element to the second initialization voltage VAINT in response to the initialization signal GIi.

The fifth and sixth transistors T51 and T61 may be defined as emission control transistors. In the embodiment, the fifth and sixth transistors T51 and T61 may be driven by different emission control signals. For example, the fifth transistor T51 may transfer the first voltage ELVDD to the first transistor T11 in response to the first emission signal EMi, and the sixth transistor T61 may be turned on in response to the second emission signal EMBi. According to the inventive concept, the fifth and sixth transistors T51 and T61 may be turned on or off at different times to be driven separately. In the embodiment, the first emission signal EMi may correspond to the i-th emission signal, and the second emission signal EMBi may be a separate signal from the first emission signal EMi. However, this is merely illustrative and the invention is not necessarily limited to any one embodiment. The first emission signal EMi and the second emission signal EMBi may also be applied at the substantially same time.

Referring to FIG. 5C, a pixel driver PC-2 may include seven transistors T12, T22, T32, T42, T52, T62 and T72 and two capacitors CST and CHD. The first transistor T12 may be defined as a driving transistor, and the second transistor T22 may be defined as a switching transistor. The third transistor T32 may be defined as a reset transistor, and the fourth transistor T42 may be defined as an anode initialization transistor. The fifth and sixth transistors T52 and T62 may be defined as emission control transistors.

In comparison to FIG. 5B, the pixel driver PC-2 may further include the seventh transistor T72. The seventh transistor 72 may be disposed between the first power supply voltage ELVDD and the drain of the first transistor T1. The seventh transistor T72 may provide the first power supply voltage ELVDD to the first transistor T12 in response to the reset signal GR. Here, the fourth transistor T7 and the third transistor T32 may be turned on at the substantially same time. In other words, at the time when the first node N1 is reset, the drain of the first transistor T12 may receive the first power supply voltage ELVDD.

The sixth transistor T62 may be driven by the i-th emission signal EMi. For example, the sixth transistor T62 and the fifth transistor T52 may be turned on at the substantially same time. According to the inventive concept, as the number of the signals GIi, GRi, EMi and GWi transferred to the pixel driver PC-2 from the scan driver SDV is reduced to four, the circuit constituting the scan driver SDV may be simplified in comparison to the circuit shown in FIG. 5B.

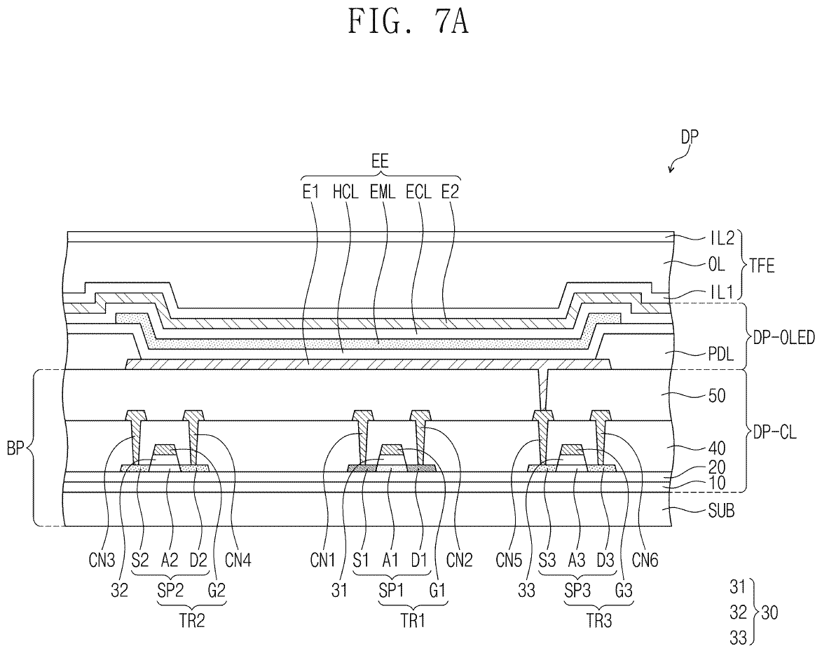

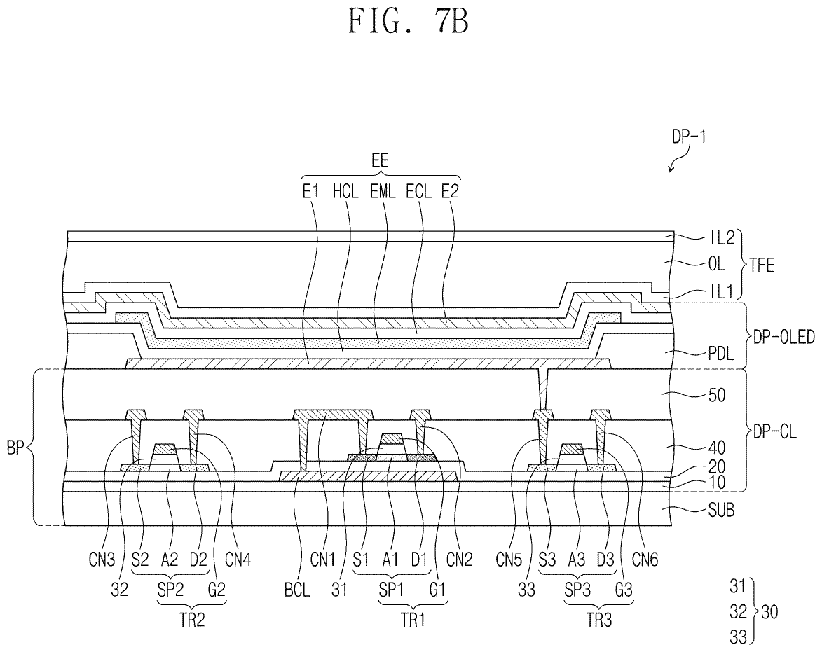

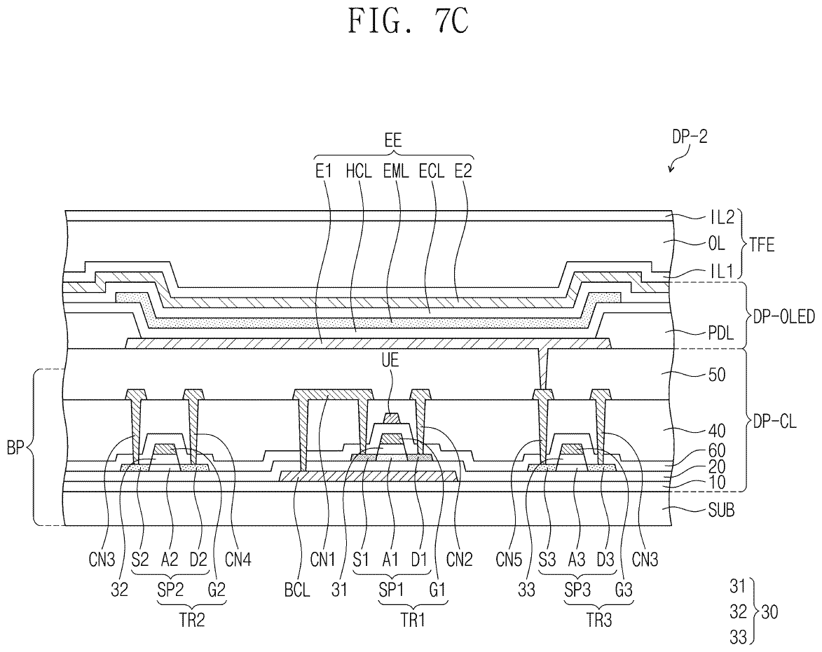

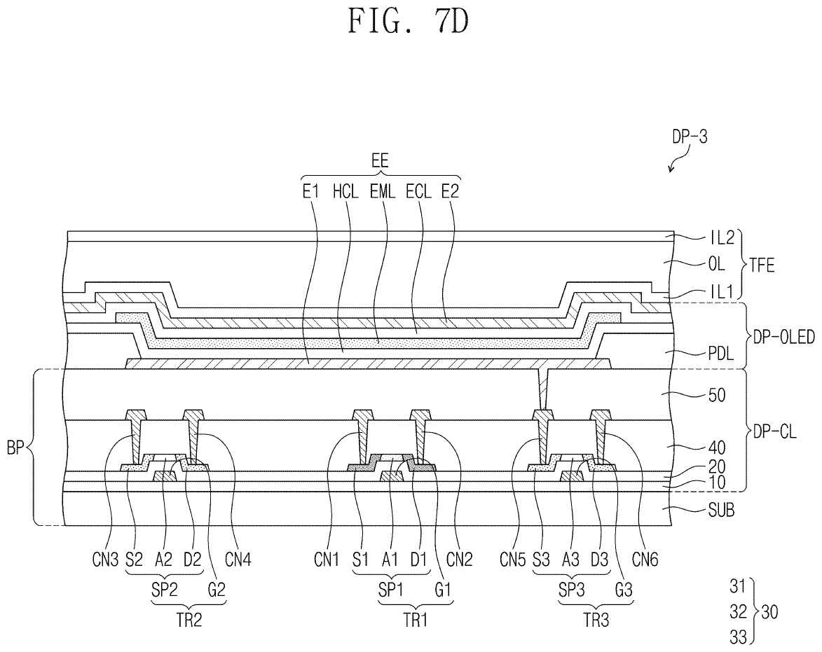

FIGS. 7A to 7D are example cross sections of a partial area of a display panel according to an embodiment of the inventive concept. Each of FIGS. 7A to 7D shows an area in which three transistor TR1, TR2 and TR3 and the light-emitting element OLED among the elements of each pixel PXij shown in FIGS. 5A to 5C are disposed. Referring to FIGS. 7A and 7D, the display panel DP may include a substrate SUB, a driving element layer DD-CL, a display element layer DP-OLED, and an encapsulation layer TFE.

The substrate SUB may include a glass substrate, a sapphire substrate, a plastic film, an organic/inorganic laminate film or the like. The substrate SUB may have a multilayer or single-layer structure. For example, the substrate SUB may have a laminated structure of a plurality of plastic films bonded by an adhesive, or a laminated structure of a glass substrate and a plastic film bonded by an adhesive. The substrate SUB may be flexible. For example, the substrate SUB may polyimide (PI). However, this is illustrative, and the substrate SUB may also be rigid and is not necessarily limited to any one embodiment.

The driving element layer DD-CL may be disposed on the substrate SUB. The driving element layer DD-CL may include a driving element and a plurality of insulation layers 10, 20, 30, 40 and 50. The foregoing three transistors T1, T2 and T6 may be elements constituting the driving element layer DD-CL. The insulation layers 10, 20, 30, 40 and 50 may include the first to fifth insulation layers 10, 20, 30, 40 and 50 sequentially laminated on the substrate SUB, but this is merely an example. The number of the insulation layers composing the driving element layers DD-CL may vary in various ways and is not necessarily limited to any one embodiment.

The three transistors TR1, TR2 and TR3 may be disposed on the substrate SUB. The three transistors TR1, TR2 and TR3 may include a first driving element TR1, a second driving element TR2, and a third driving element TR3. In the embodiment, a lower conductive layer BML and the first insulation layer 10 may be disposed between the three transistors TR1, TR2 and TR3 and the substrate SUB.

The first insulation layer 10 may be disposed on the substrate SUB and may cover the top surface of the substrate SUB. The first insulation layer 10 may include a barrier layer. For example, the first insulation layer 10 may prevent oxygen or moisture flowed via the substrate SUB from penetrating into the pixel PXij.

The second insulation layer 20 may be disposed on the first insulation layer 10 and may cover the lower conductive layer BML. The second insulation layer 20 may completely cover the substrate SUB. The second insulation layer 20 may include a buffer layer. For example, the second insulation layer 20 may reduce surface energy of a surface on which the driving element layer DP-CL is provided so that the pixel PXij is stably provided on the substrate SUB. At least one of the barrier layer and the buffer layer may be provided in plural or may be omitted. Furthermore, in the display panel according to an embodiment, the first insulation layer 10 and/or the second insulation layer 20 may be also omitted, and is not necessarily limited to any one embodiment.

The first thin-film transistor TR1 may include a first semiconductor pattern SP1 and a first gate G1. The first thin-film transistor TR1 may be a driving transistor disposed on a current path between the first power line PL1 and the light-emitting element OLED to control the amount of a current flowing through the light-emitting element, but is not necessarily limited thereto. The first semiconductor pattern SP1 may include a first source S1, a first drain D1, and a first channel A1.

In the embodiment, the first semiconductor pattern SP1 may include an oxide semiconductor. For example, the first semiconductor pattern SP1 may include at least one of indium, gallium, or zinc. The first semiconductor pattern SP1 may include a crystalline structure. For example, the first semiconductor pattern SP1 may include a crystalline-oxide semiconductor. The first semiconductor pattern SP1 may be provided by crystallizing an oxide semiconductor material. The first source S1, the first drain D1, and the first channel A1 may be divided according to the conductivity. For example, the first channel A1 may have a relatively low conductivity in comparison to the first source S1 and the first drain D1, and have the semiconductor properties. Each of the first source S1 and the first drain D1 may have a higher conductivity than the first channel A1 and have the conductive properties.

Each of the first source S1 and the first drain D1 may be provided through doping or reduction. For example, in the semiconductor pattern, a highly doped area with a relatively high dopant concentration may have a high conductivity. A portion of the semiconductor pattern may be doped to be a source/drain, and the other portion may be a channel. The dopant may be a p-type dopant or an n-type dopant, and is not necessarily limited to any one embodiment. In the embodiment, each of the first source S1 and the first train D1 may be doped with an n-type dopant.

Alternatively, for example, in the oxide semiconductor pattern, a reduction area may have a high conductivity in comparison to an unreduced area. Since a metal oxide composing the oxide semiconductor pattern is precipitated as a metal through reduction processes, an area in which the metal oxide is reduced may be a source/drain, and the other area may be a channel.

In the embodiment, the first source S1 and the first drain D1 may be provided in the first semiconductor pattern SP1. However, this is illustrative, and the source/drain of the first thin-film transistor T1 may be provided as a separate conductive pattern connected to the first semiconductor pattern SP1, and is not necessarily limited to any one embodiment.

The first gate G1 may be disposed on the semiconductor pattern of the first thin-film transistor TR1. The first gate G1 may overlap the first channel A1. A first insulation pattern 31 may be disposed between the first gate G1 and the semiconductor pattern. The first insulation pattern 31 may be aligned with the first gate G1 and patterned. The first insulation pattern 31 may be a gate insulation layer, and the first thin-film transistor TR1 is shown as a top-gate structure. However, this is illustrative and is not necessarily limited to any one embodiment. The first insulation pattern 31 may be provided as an integrated layer to cover the entire area of the substrate SUB, and the first thin-film transistor TR1 may have a bottom-gate structure.

The second thin-film transistor TR2 may include a second gate G2 and a second semiconductor pattern SP2. The second thin-film transistor TR2 may be an initialization transistor T4 (see FIG. 5A) turned on via the foregoing initialization scan line GILi to provide, to the pixel circuit, the initialization voltage VINT transferred via the first initialization line VIL1, but is not necessarily limited thereto.

The second semiconductor pattern SP2 may be disposed on the same layer as the first semiconductor pattern SP1. In the embodiment, the second semiconductor pattern SP2 may include an amorphous oxide semiconductor. The second semiconductor pattern SP2 may include an oxide semiconductor having a high mobility. For example, the second semiconductor pattern SP2 may have the mobility of about 30 cm²/v·s or higher.

The second semiconductor pattern SP2 may include at least one of indium, tin, gallium, or zinc. For example, the second semiconductor pattern SP2 may include indium, tin, gallium, and zinc, wherein a composition ratio thereof is about 60 to about 80 wt % of indium, about 0.5 to about 8 wt % of tin, about 5 to about 15 wt % of gallium, and about 10 to about 30 wt % of zinc, but is not necessarily limited thereto. The second semiconductor pattern SP2 with a high mobility may include an oxide semiconductor with various compositions and is not necessarily limited to any one embodiment.

The second semiconductor pattern SP2 may have a different crystalline structure from the first semiconductor pattern SP1. For example, the second semiconductor pattern SP2 may be a metal oxide semiconductor pattern without needing crystallization processes. The second semiconductor pattern SP2 may be divided into a second source S2 having a relatively high conductivity and conductor characteristics, a second drain D2, and a second channel A2 having a relatively low conductivity and semiconductor characteristics. In the embodiment, each of the second source S2 and the second train D2 may have a high n-type dopant concentration. This is illustrative, and to the extent that an element, such as the second semiconductor pattern SP2, is not described in detail with respect to this figure, it may be understood that the element is at least similar to a corresponding element that has been described elsewhere within the present disclosure, such as the first semiconductor pattern SP1.

The second gate G2 may be disposed over the second semiconductor pattern SP2 with the second insulation pattern 32 interposed therebetween. The second gate G2 may overlap the second channel A2. When the second thin-film transistor TR2 may be the initialization transistor T4 (see FIG. 5), the second gate G2 may be a corresponding initialization scan line among the initialization scan lines GIL1 to GILm. A second insulation pattern 22 may be disposed between the second gate G2 and the second semiconductor pattern SP2. The second thin-film transistor TR2 is shown as a top-gate structure. However, this is only illustrative. The second thin-film transistor TR2 may also have a bottom-gate structure and is not necessarily limited to any one embodiment.

The third thin-film transistor TR3 may include a third gate G3 and a third semiconductor pattern SP3. The third thin-film transistor TR3 may be an emission control transistor T6 (see FIG. 5A) disposed on a current path between the first thin-film transistor TR1 and the light-emitting element OLED and configured to provide, to the light-emitting element OLED, a driving current transferred by the first thin-film transistor TR1 in response to a signal transferred via the foregoing emission line EMLi, but is not necessarily limited thereto.

The third thin-film transistor TR3 may have the same structure as the second thin-film transistor TR2. For example, the third thin-film transistor TR3 may have a top-gate structure in which the third gate G3 is overlapped over the third semiconductor pattern SP3 with the third insulation pattern 33 interposed therebetween, include a third semiconductor pattern SP3 disposed on the same layer as the first thin-film transistor TR1, and include a third source S3, a third drain D3, and a third channel A3 provided in the third semiconductor pattern SP3. The third semiconductor pattern SP3 may be provided with an amorphous oxide semiconductor, and each of the third source S3 and the third drain D3 may include an n-type dopant. For example, the second semiconductor pattern SP2 and the third semiconductor pattern SP3 may include the same material and be patterned through the same processes. However, this is illustrative and is not necessarily limited to any one embodiment. The third semiconductor pattern SP3 may include a different material from the second semiconductor pattern SP2.

According to the embodiment, the first thin-film transistor TR1 serving as a driving transistor may have a relatively wide driving range in comparison to the second and third thin-film transistors TR2 and TR3 each serving as a switching transistor. The first channel A1 may be provided with a crystalline oxide semiconductor to secure a relatively wide driving range in comparison to the second and third channels A2 and A3 provided with an amorphous oxide semiconductor. The first channel A1 according to the embodiment may have a driving range of about 0.39 V or higher. Accordingly, the pixel PXij may easily represent various gray scales.

In addition, the second and third thin-film transistors TR2 and TR3, each serving as the switching transistor, may have relatively high charge mobilities and shorter channel lengths in comparison to the first transistor TR1 serving as the driving transistor. The second and third channels A2 and A3 are provided with an amorphous oxide semiconductor and thus secure relatively high charge mobilities and shorter channel lengths in comparison to the first channel A1. Each of the second and third channels A2 and A3 in the embodiment may have a charge mobility of about 30 cm²/v·s or higher and the length of about 4 μm or shorter. Accordingly, the switching transistor having reduced leak current and improved on-off characteristics may facilitate a design of a display panel with a high resolution.

As described above, the first to third insulation patterns 31, 32, and 33 may be connected with each other to provide an integrated layer. Here, the third insulation layer 30 may be provided as a single insulation layer with an integrated shape that is not the separated multiple patterns 31, 32 and 33, and is not necessarily limited to any one embodiment.

The driving element layer DP-CL may further include a plurality of connection electrodes CN1, CN2, CN3, CN4, CN5 and CN6. The first connection electrode CN1 may be connected to the source S1 of the first thin-film transistor TR1 and the second connection electrode CN2 may be connected to the drain D1 of the first thin-film transistor TR1. The third connection electrode CN3 may be connected to the source S2 of the second thin-film transistor TR2 and the fourth connection electrode CN4 may be connected to the drain D2 of the second thin-film transistor TR2. The fifth connection electrode CN5 may be connected to the source S3 of the third thin-film transistor TR3 and the sixth connection electrode CN6 may be connected to the drain D3 of the third thin-film transistor TR3.

The fifth insulation layer 50 may be disposed on the fourth insulation layer 40 to cover the connection electrodes CN1, CN2, CN3, CN4, CN5 and CN6. The light-emitting element OLED may be connected to the driving element layer DP-CL through the contact hole provided in the fifth insulation layer 50.

In the embodiment, each of the first to fifth insulation layers 10, 20, 30, 40 and 50 may include an inorganic and/or organic layer. By way of example, the first and second insulation layers 10 and 20 each may include silicon nitride and/or silicon oxide, and each of the first to third insulation patterns 31, 32 and 33 composing the third insulation layer 30 may include silicon oxide. The fourth insulation layer 40 may include sequentially laminated with silicon oxynitride layer and silicon nitride layer, and the fifth insulation layer 50 may include an organic layer. However, this is illustrative and the material or laminate type of each of the first to fifth insulation layers 10, 20, 30, 40 and 50 may vary in various ways, and is not necessarily limited to any one embodiment.

The display element layer DP-OLED may be disposed on the driving element layer DP-CL. The display element layer DP-OLED may include a light-emitting element OLED and a pixel definition layer PDL. The light-emitting element OLED may include a first electrode E1, a hole control layer HCL, an emission layer EML, an electron control layer ECL, and a second electrode E2.

The first electrode E1 may be disposed on the fifth insulation layer 50. The first electrode E1 may penetrate through the fifth insulation layer 50 and may be connected to the fifth connection electrode CN5. This is illustrative and is not necessarily limited to any one embodiment. If the first electrode E1 may be connected to the third thin-film transistor T3, the connection may be performed through a separate additive connection electrode or directly to the source S3 of the third thin-film transistor TR3.

The pixel definition layer PDL may be disposed on the fifth insulation layer 50. The pixel definition layer PDL may expose at least a portion of the first electrode E1. For example, in the pixel definition layer PDL, an opening may be defined to expose a prescribed portion of the first electrode E1.

The hole control layer HCL may be disposed on the first electrode E1 and the pixel definition layer PDL. The hole control layer HCL may be disposed in common in the emission area and the non-emission area. The hole control layer HCL may include a layer having a high hole mobility so that the holes easily move from the first electrode E1 to the emission layer EML. For example, the hole control layer HCL may include at least one of a hole transport layer, a hole injection layer, or an electron blocking layer, and each of the layers may have a single layer or multilayer structure.

The emission layer EML may be disposed on the hole control layer HCL. The emission layer EML may be disposed in an area corresponding to the opening of the pixel definition layer PDL. The light emitting layer EML may include an organic material and/or inorganic material. The light emitting layer EML may generate light of one of red, green, and blue colors.

The electron control layer ECL may be disposed on the light emitting layer EML and the hole control layer HCL. The electron control layer ECL may be disposed in common in the emission area and the non-emission area. The electron control layer ECL may include a layer having a high electron mobility so that the electrons easily move from the second electrode E2 to the emission layer EML. For example, the electron control layer ECL may include at least one of an electron transport layer, an electron injection layer, or a hole blocking layer, and each of the layers may have a single layer or multilayer structure.

The second electrode E2 may be disposed on the electron control layer ECL. The second electrode E2 may be disposed in common to the pixels PX. For example, the second electrode E2 may be provided in an integrated shape on the emission layer EML of the pixel layers PX. However, this is illustrative and is not necessarily limited to any one embodiment. The second electrode E2 may be provided as a separated pattern for each of the pixels PX. The second electrode E2 may be semi-transmissive or transmissive. The second electrode E2 may be provided in various types, for example, a transparent conductive oxide layer, a transmissive metal layer with a thin-film thickness, a laminated layer of a metal layer/oxide layer, or the like. When the light-emitting element OLED has a bottom emission structure, the second electrode E2 may be a reflective electrode.

An encapsulation layer TFE may be disposed on the display element layer DD-OLED. The encapsulation layer TFE may include inorganic layers and organic layers. In the embodiment, the encapsulation layer TFE is shown as having a first inorganic layer IL1, an organic layer OL and a second inorganic layer IL2 that are sequentially laminated, but the laminated structure of the layers composing the encapsulation layer TFE may be changed in various ways.

The first inorganic layer IL1 and the second inorganic layer IL2 may include inorganic materials and protect the pixels from moisture/oxygen. The first inorganic layer IL1 and the second inorganic layer IL2 may have the same materials or different materials. The organic layer OL may include an organic material and protect the light-emitting element layer DD-OLED or the driving element layer DD-CL from foreign matters.

Referring to FIG. 7B, the display panel DP-1 may further include a lower conductive layer BCL. The lower conductive layer BCL may be disposed on the first insulation layer 10. The lower conductive layer BCL may block light incident to the first thin-film transistor TR1 from the bottom. The lower conductive layer BCL may be a light-shielding pattern or include a block matrix or reflective conductive materials. When including conductive materials, the lower conductive layer BCL may be electrically floated or connected to the first thin-film transistor TR1.

In the embodiment, the lower conductive layer BCL may be connected to the source S1 of the first thin-film transistor TR1. For example, the first connection electrode CN1 may be connected to the lower conductive layer BCL and the source S1 of the first thin-film transistor TR1. Accordingly, the first thin-film transistor TR1 may have a source-sync structure and a high driving range of the first channel A1. However, this is illustrative and is not necessarily limited to any one embodiment. The lower conductive layer BCL may be connected to a gate or drain of the first thin-film transistor TR1, electrically floated, transferred with a static voltage, or omitted. The second thin-film transistor TR2 or the third thin-film transistor TR3 may have a gate-sync structure. Accordingly, the channel length becomes short and thus the second thin-film transistor TR2 or the third thin-film transistor may be designed to be beneficial to high speed driving. However, this is illustrative and is not necessarily limited to any one embodiment. The display panel DP-1, according to an embodiment of the inventive concept, may have various structure.

Referring to FIG. 7C, the display panel DP-2 may further include an upper electrode UE. The upper electrode UE may be disposed on the sixth insulation layer 60 interposed between the third insulation layer 30 and the fourth insulation layer 40. The upper electrode UP may be disposed to overlap the first gate G1 with the sixth insulation layer 60 interposed therebetween in a plan view. The sixth insulation layer 60 may be disposed on the second and third insulation layers 20 and 30 to cover the first thin-film transistor TR1.

A portion in which the upper electrode UE and the first gate G1 overlap in a plan view may serve as the capacitor CST (see FIG. 5A) constituting the pixel circuit. According to the inventive concept, the capacitor CST may be provided together with the first gate G1 of the first thin-film transistor TR1 to secure a capacitor area and a high resolution pixel circuit. However, this is illustrative and is not necessarily limited to any one embodiment. The upper electrode UE may be omitted or the capacitor may be provided at another position.

Referring to FIG. 7D, in the display panel DP-3, each of the thin-film transistors TR1, TR2 and TR3 may have a bottom-gate structure. The first to third gates G1, G2 and G3 may be disposed between the first insulation layer 10 and the second insulation layer 20, and the semiconductor patterns SP1, SP2 and SP3 may be disposed between the second insulation layer 20 and the fourth insulation layer 40. Here, the sources S1, S2 and S3 and drains D1, D2 and D3 of the semiconductor patterns SP1, SP2 and SP3 may be reduced in processes for providing contact holes in the fourth insulation layer 40. The contact holes in the fourth insulation layer 40 may be holes through which each of the connection electrodes CN1, CN2, CN3, CN4, CN5 and CN6 is connected to the corresponding semiconductor patterns SP1, SP2 and SP3.

The display panels DP, DP-1, DP-2 and DP-3, according to the inventive concept, enables an independent design according to a function of each of the thin-film transistors by providing the semiconductor pattern SP1 of the first thin-film transistor TR1 serving as the driving transistor with a crystalline oxide semiconductor and providing the semiconductor patterns SP2 and SP3 of the thin-film transistors TR2 and TR3 serving as the switching transistors with an amorphous oxide semiconductor. Therefore, the first thin-film transistor TR1 may secure a high driving range to make it possible to provide a display panel with various grayscale representations. In addition, the second and third thin-film transistors TR2 and TR3 have high mobilities and short channel lengths to make it possible to provide a pixel driving circuit with reduced leakage current.

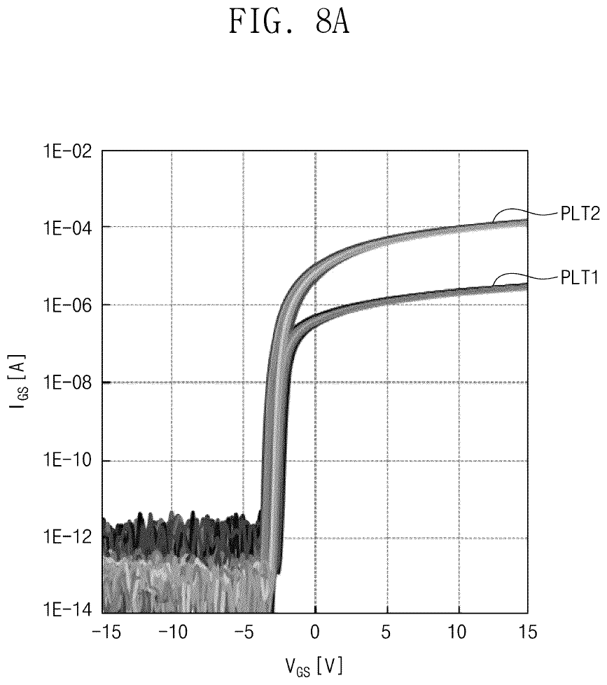

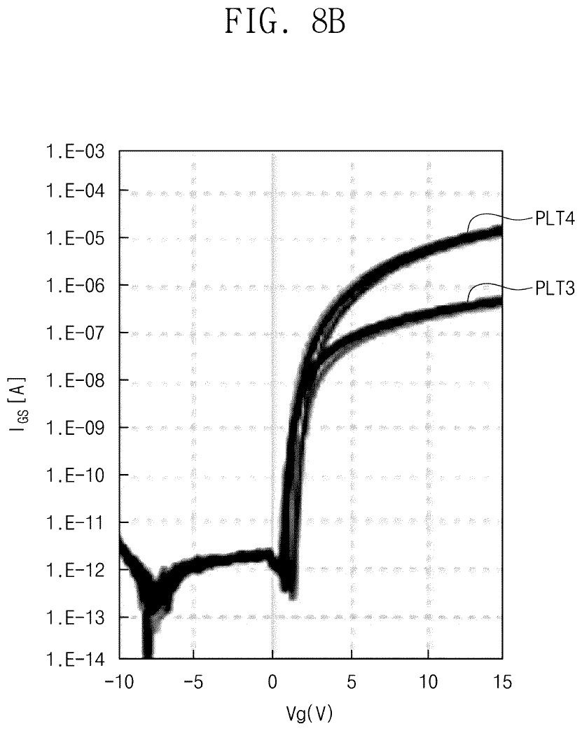

FIGS. 8A and 8B are graphs of the current-voltage characteristics of a semiconductor pattern according to an embodiment of the inventive concept. FIG. 8A shows the current-voltage characteristics of the second semiconductor pattern SP2, and FIG. 8B shows current-voltage characteristics of the first semiconductor pattern SP1. Hereinafter, the inventive concept will be described with reference to FIGS. 8A and 8B.

Referring to FIG. 8A, it may be understood that the second semiconductor pattern SP2 is provided with an amorphous oxide semiconductor material to permit the channel of the second thin-film transistor TR2 to have a high mobility. Accordingly, a rapid switching operation is possible for the second thin-film transistor TR2, and thus it is possible to provide a switching transistor with improved on-off characteristics.

Referring to FIG. 8B, the first semiconductor pattern SP1 may be provided with a crystalline oxide semiconductor material to secure a wide driving range of a gate voltage of the first thin-film transistor TR1. The driving range of the first thin-film transistor TR1 at a low gray level may be about 0.45 V or higher, especially 0.9 V or higher.

FIG. 8B is a graph of the current-voltage characteristics when the channel length is about 5 μm. When the driving range at a low gray level is measured as a threshold voltage difference ΔVth controllable in a current range of about 10 pA to about 1 nA, the driving range in FIG. 8B may appear as about 0.99 V. According to the inventive concept, the first semiconductor pattern SP1 may be provided with the crystalline oxide semiconductor to provide a wide driving range. Since the driving range of the gate voltage of the first thin-film transistor TR1 is wide, the gray level of light emitted from the light-emitting element may be finely controlled by changing the amplitude of the gate voltage. Accordingly, the display panel with a high resolution and increased display quality may be provided. Furthermore, the threshold voltage difference ΔVth measured after driving the first semiconductor pattern SP1 for 12 hours appears as about 15.6 mV, and the threshold voltage difference ΔVth measured after driving for 55 hours appears as about 39 mV. Accordingly, the first semiconductor pattern SP1 may have the increased reliability while having a crystalline structure.

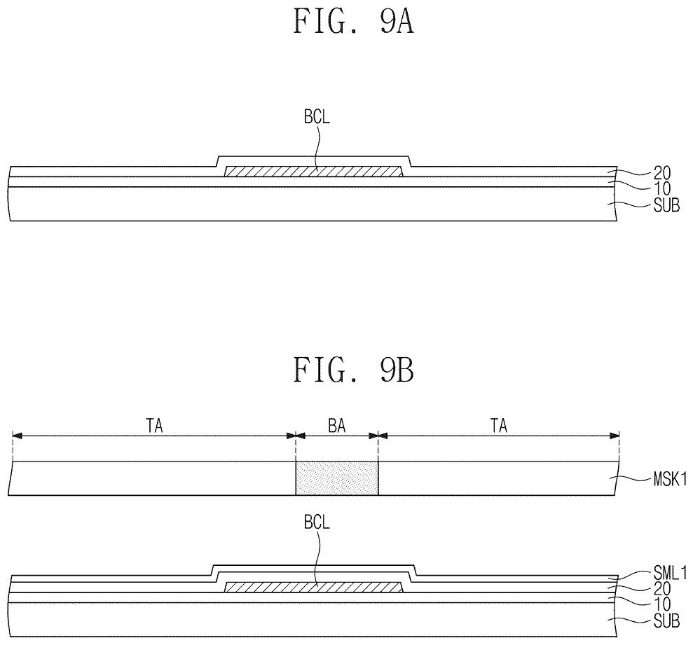

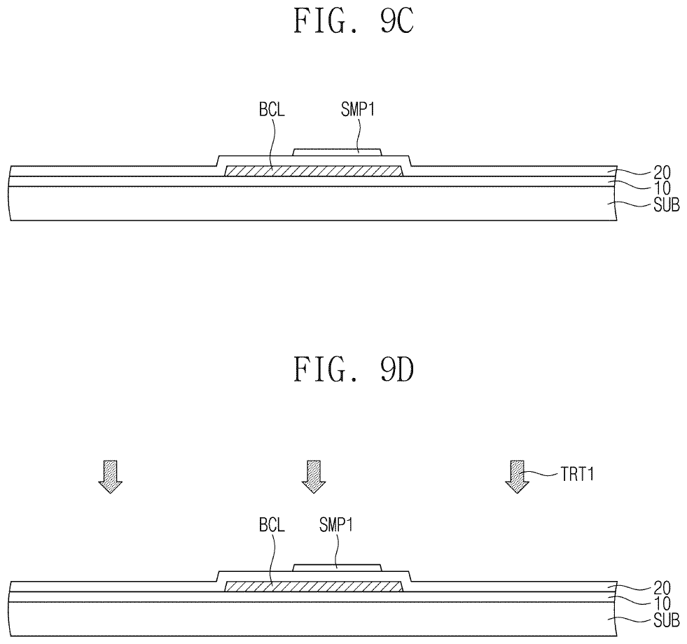

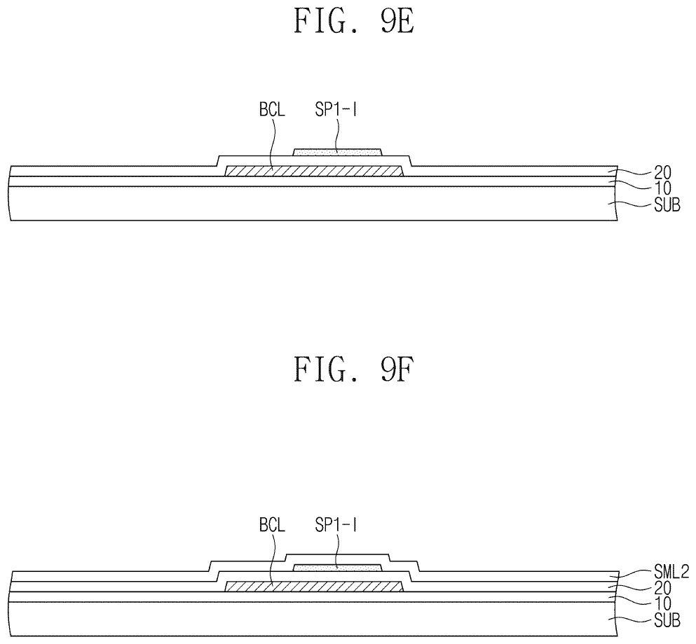

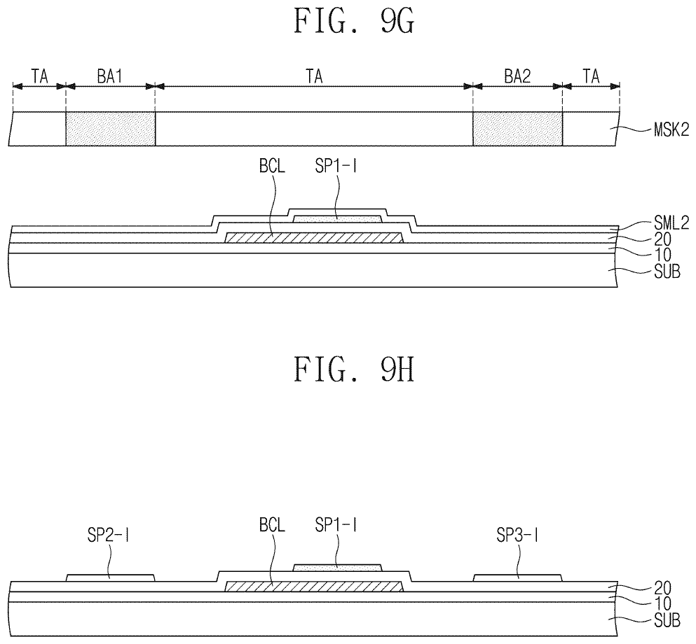

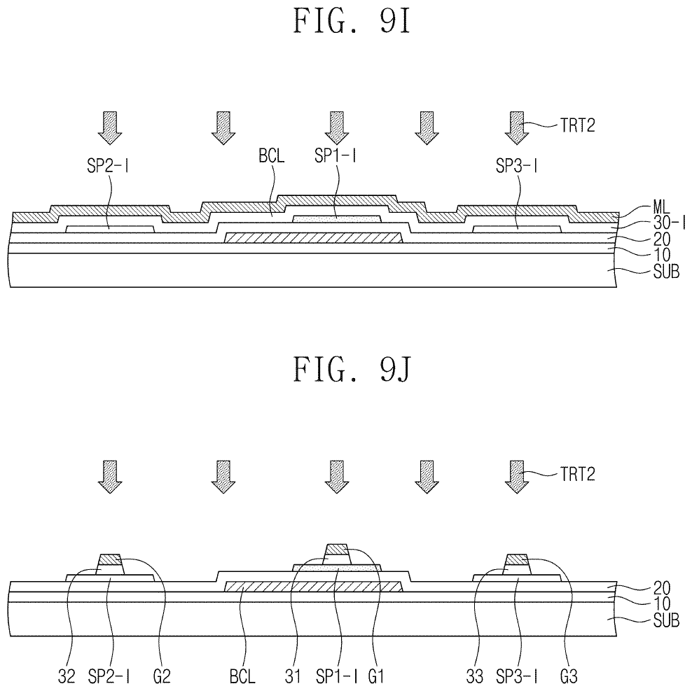

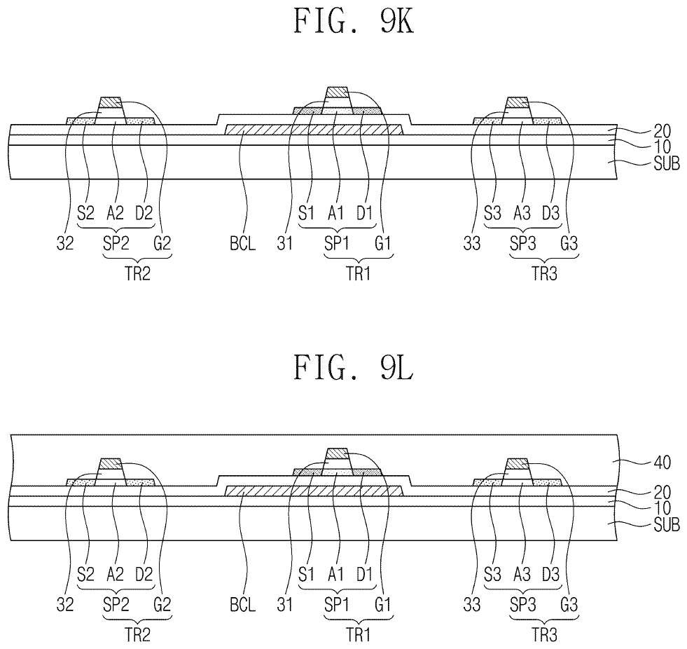

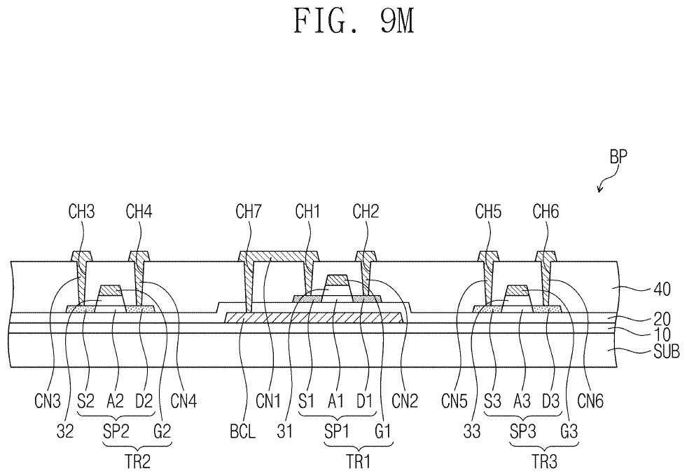

FIGS. 9A to 9M are cross-sectional views showing a method of manufacturing a display panel according to an embodiment of the inventive concept. FIGS. 9A to 9M show an example manufacturing method of the display panel SP-1 shown in FIG. 7B. Hereinafter, the inventive concept will be described with reference to FIGS. 9A to 9M. Like reference numbers are given to like components as those described in FIGS. 1 to 8B, and to the extent that an element is not described in detail with respect to this figure, it may be understood that the element is at least similar to a corresponding element that has been described elsewhere within the present disclosure.

Referring to FIG. 9A, the first insulation layer 10, the lower conductive layer BCL, and the second insulation layer 20 may be laminated on the substrate SUB. The first insulation layer 10 may be provided by depositing or coating an insulation material. The lower conductive layer BCL may be patterned after depositing a conductive material on the first insulation layer 10. However, this is illustrative and is not necessarily limited to any one embodiment. The lower conductive layer BCL may be provided in solution processes of coating or the like, other than the deposition. Then the insulation material is deposited or coated to provide the second insulation layer 20 covering the lower conductive layer BCL.

Referring to FIGS. 9B and 9C, the first pattern SMP1 may be provided on the second insulation layer 20. After the first semiconductor layer SML1 is provided on the second insulation layer 20, the first semiconductor layer SMI1 may be patterned using a mask MSK1. A portion corresponding to the light shielding area BA of the first mask MSK1 remains on the first semiconductor layer SML1 to provide the first pattern SMP1, and a portion corresponding to the transmission area TA of the first mask MSK1 may be removed. The first pattern SMP1 may be provided on an area overlapping the lower conductive layer BCL. However, this is illustrative. The first pattern SMP1 may be patterned through various manners and is not necessarily limited to any one embodiment.

Referring to FIGS. 9D and 9E, the first pattern SMP1 may be subject to first treatment TRT1 to provide a first initial semiconductor pattern SP1-I. The first treatment TRT1 may be crystallization. The first treatment TRT1 may be heat treatment, but is not necessarily limited to any one embodiment if the first pattern SMP1 may be crystallized. Through the first treatment TRT1, the first initial semiconductor pattern SP1-I crystallized from the first pattern SMP1 may be provided.

Referring to FIG. 9F, the second semiconductor layer SML2 may be provided thereafter. The second semiconductor layer SML2 may be provided by depositing the second semiconductor material on the second insulation layer 20. The second semiconductor layer SML2 may directly cover the first initial semiconductor pattern SP1-I. For example, the second semiconductor layer SML2 may contact the first initial semiconductor pattern SP1-I.

Referring to FIGS. 9G and 9H, a second initial semiconductor pattern SP2-I and a third initial semiconductor pattern SP2-I may be provided thereafter. After the second semiconductor layer SML2 is provided, the second semiconductor layer SML2 may be patterned using a second mask MSK2. A portion corresponding to the first light shielding area BA1 of the second mask MSK2 remains on the second semiconductor layer SML2 to provide the second initial semiconductor pattern SP2-I, a portion corresponding to the second light shielding area BA2 of the second mask MSK2 remains to provide the third initial semiconductor pattern SP3-I, and a portion corresponding to the transmission area TA of the second mask MSK2 may be removed.

In the embodiment, the second initial semiconductor pattern SP2-1 and the third initial semiconductor pattern SP2-I may be substantially simultaneously provided through a single mask MSK2. For example, the second initial semiconductor pattern SP2-I and the third initial semiconductor pattern SP3-I may be provided with the same material. Accordingly, the processes for providing the second initial semiconductor pattern SP2-I and the third initial semiconductor pattern SP3-I may be simplified and the process cost may be reduced. However, this is illustrative and is not necessarily limited to any one embodiment. The second initial semiconductor pattern SP2-I and the third initial semiconductor pattern SP3-I may also be respectively provided in separate processes through different masks or with different materials.

In the embodiment, the second initial semiconductor pattern SP2-1 and the third initial semiconductor pattern SP2-I may be provided on the same layer as the first initial semiconductor pattern SP1-I. The first initial semiconductor pattern SP1-I with the crystalline structure is not influenced by an etchant used in patterning the second initial semiconductor pattern SP2-1 and the third initial semiconductor pattern SP2-I. The etchant may have a composition ratio of nitric acid of about 7%, sulfuric acid of about 0.5% and an additive agent of about 1%, but the composition ratio is not necessarily limited thereto. Even though the first initial semiconductor pattern SP1-I is exposed to the etchant during patterning the second initial semiconductor pattern SP2-1 and the third initial semiconductor pattern SP2-I, only a portion exposed to light in the second semiconductor layer SMP2 is removed and the first initial semiconductor pattern SP1-I may stably remain. Accordingly, even if the first to third initial semiconductor patterns SP1-I, SP2-I and SP3-I are provided on the same layer, the first initial semiconductor patter SP1-I provided earlier is unaffected to increase the process reliability. Furthermore, since the first to third initial semiconductor patterns SP1-I, SP2-I and SP3-I are provided on the same layer, the processes are simplified and the layered structure of the display panel may be simplified. However, this is illustrative and is not necessarily limited to any one embodiment. The second initial semiconductor pattern SP2-I and the third initial semiconductor pattern SP3-I may also be provided on a layer different from the first initial semiconductor pattern SP1-I.

Referring to FIGS. 9I to 9K, the gates G1, G2 and G3 and the insulation patterns 31, 32 and 33 may be provided thereafter. An initial third insulation layer 30-I and the metal layer ML covering the initial first to third semiconductor patterns SP1-I, SP2-I and SP3-I may be sequentially provided on the second insulation layer 20. The initial third insulation layer 30-I may be provided by depositing or coating an insulation material, and the metal layer ML may be provided by depositing or coating a metal material. The metal layer ML may be provided with a conductive material other than a metal, but is not necessarily limited to any one embodiment.

The initial third insulation layer 30-I and the metal layer ML are subject to second treatment TRT2 to provide the first to third insulation patterns 31, 32 and 33 and the first to third gates G1, G2 and G3. The second treatment TRT2 may be an etching process. The first to third gates G1, G2 and G2 may be provided from the metal layer ML using a mask. Then, the first to third insulation patterns 31, 32 and 33 may be provided by using the first to third gates G1, G2 and G3 as masks. Accordingly, the first to third insulation patterns 31, 32 and 33 may be arranged with the first to third gates G1, G2 and G3.

The initial first to third semiconductor patterns SP1-I, SP2-I and SP3-I are reduced by the second treatment TRT2 to provide the first to third semiconductor patterns SP1, SP2 and SP3. Exposed portions, not covered by the first to third semiconductor patterns SP1, SP2 and SP3 and the first to third gates G1, G2 and G3, in the initial first to third semiconductor patterns SP1-I, SP2-I and SP3-I, may be reduced by the second treatment TRT2 to precipitate a metal. Accordingly, the sources S1, S2 and S3 and the drains D1, D2 and D3 with high conductivities may be provided. Here, the sources S1, S2 and S3 and the drains D1, D2 and D3 may be provided as areas having an n-type dopant.

The initial first to third semiconductor patterns SP1-I, SP2-I and SP3-I are provided as the first to third semiconductor patterns SP1, SP2 and SP3 each including a source, a drain and a channel. The channels A1, A2 and A3 of the initial first to third semiconductor patterns SP1-I, SP2-I and SP3-I may be self-aligned with the gates G1, G2 and G3 and the insulation patterns 31, 32 and 33. According to the inventive concept, the first to third thin-film transistors TR1, TR2 and TR3 may include the semiconductor patterns SP1, SP2 and SP3 disposed on the same layer. However, this is illustrative and is not necessarily limited to any one embodiment. If the first semiconductor pattern SP1 is provided with a crystalline structure and the second and third semiconductor patterns SP2 and SP3 are provided with an amorphous structure, the positions and structures of the first to third thin-film transistors TR1, TR2 and TR3 may be changed in various ways.

Then, referring to FIG. 9L, the fourth insulation layer 40 may be provided. The fourth insulation layer 40 may be provided by depositing or coating an insulation material. The fourth insulation layer 40 may be provided by sequentially laminating a plurality of insulation layers. The fourth insulation layer 40 may cover the thin-film transistors TR1, TR2 and TR3.

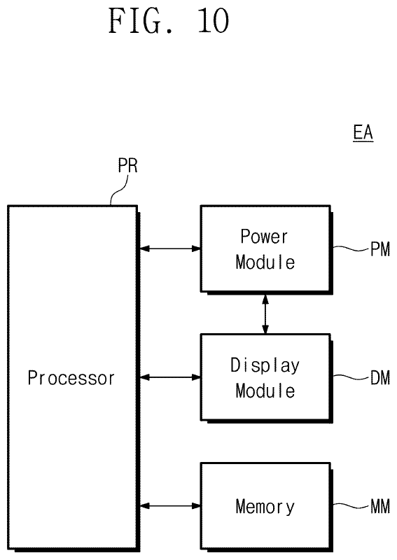

Then, referring to FIG. 9M, the connection electrodes CN1, CN2, CN3, CN4, CN5 and CN6 may be provided. The plurality of contact holes CH1, CH2, CH3, CH4, CH5 and CH6 are provided in the fourth insulation layer 40, and the connection electrodes CN1, CN2, CN3, CN4, CN5 and CN6 may be respectively connected to the corresponding thin-film transistors TR1, TR2 and TR3 through the contact holes CH1, CH2, CH3, CH4, CH5 and CH6. According to the inventive concept, a contact hole CH7 may be further provided to penetrate through the second insulation layer 20 and the fourth insulation layer 40. The first connection electrode CN1 may be additionally connected to the lower conductive layer BCL through the contact hole CH7. Accordingly, the source S1 of the first transistor TR1 and the lower conductive layer BCL may be electrically connected. However, this is illustrative and is not necessarily limited to any one embodiment. The disposition of the connection electrodes CN1, CN2, CN3, CN4, CN5 and CN6 may be changed in various ways, and at least a portion thereof may be omitted or further added. FIG. 10 is a block diagram of an electronic device EA according to an embodiment.

Referring to FIG. 10, the electronic device EA according to an embodiment may include a display module DM, a processor PR, a memory MR, and a power module PM.

The display module DM may display an image. The image may include a static image as well as a dynamic image. The processor PR may include at least one of a central processing unit (CPU), an application processor (AP), a graphic processing unit (GPU), a communication processor (CP), an image signal processor (ISP), or a controller. The processor PR may be configured to control an operation of the display module DM.

In the memory MR, data information necessary for an operation of the processor PR or the display module DM may be stored. When the processor PR executes an application stored in the memory MR, an image data signal and/or an input control signal may be transmitted to the display module DM, and the display module DM may process the received signal and output image information through a display screen.

The power module PM may include a power supply module such as a power adapter or battery unit, and a power conversion module which converts the power provided by the power supply module and generates power necessary for an operation of the electronic device EDE.

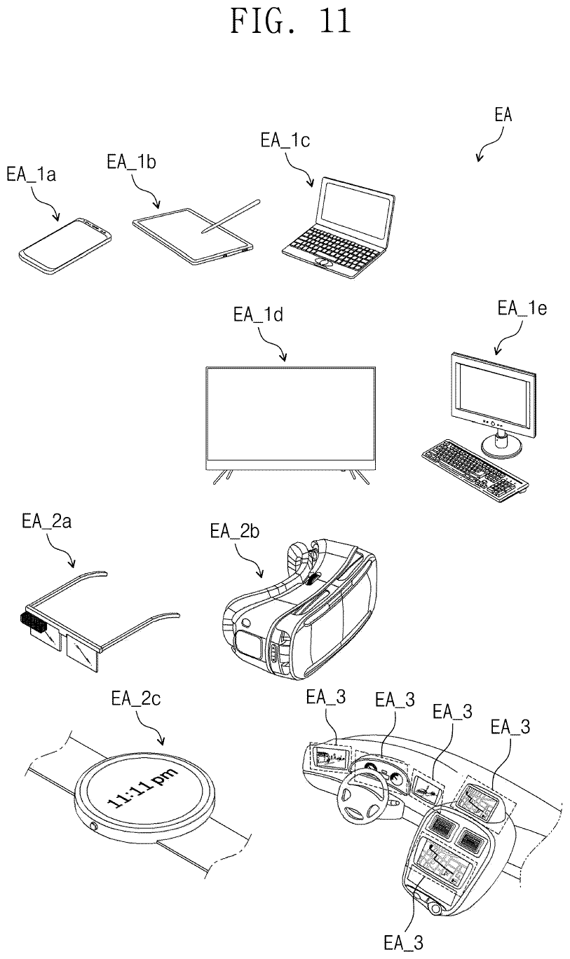

FIG. 11 shows schematic diagrams of an electronic device according to various embodiments.

Referring to FIG. 11, various electronic devices according to embodiments to which a display device is applied may include not only an electronic device for displaying an image such as a smart phone EA_1a, a tablet PC EA_1b, a laptop computer EA_1c, a TV EA_1d, and a monitor EA_1e for a desk, but also a wearable electronic device including a display module such as smart glasses EA_2a, a head-mounted display EA_2b, and a smart watch EA_2c, and an electronic device EA_3 for vehicles including a display module such as a room mirror display and a center information display (CID), which is disposed on a car's instrument cluster, center fascia, and dashboard.

The electronic apparatus in FIG. 11 may include the components illustrated in FIG. 10. For example, the smartphone EA_1a may include the display module 11, the processor 12, the memory 13, and the power module 14 which are illustrated in FIG. 10. The smartphone EA_1a may further include a communication module and a battery device. Power provided by the battery device may be converted through the power module 14 and provided to the processor 12, the memory 13, and the display module 11. In an embodiment, a display device applied to the smartphone EA_1a may include the display module 11 and further include the power module 14. The processor 12 and the memory 13 may be provided in the form of a chip mounted on a mother board that is an external device, but are not limited thereto.

According to the embodiments, the switching transistors with a high mobility and the driving transistor with a wide driving range may be provided together. Accordingly, low grayscale representation may be stably achieved and a high resolution display panel may be easily designed. Furthermore, the process reliability for manufacturing the display panel may be increased.

While this invention has been described with reference to exemplary embodiments thereof, it will be clear to those of ordinary skill in the art to which the invention pertains that various changes and modifications may be made to the described embodiments without departing from the spirit and technical area of the invention. Thus, the scope of the inventive concept shall not necessarily be restricted or limited by the foregoing description.

What is claimed is:

1. A display panel, comprising:
a substrate;
a plurality of light-emitting elements disposed on the substrate; and
a plurality of pixel drivers respectively electrically connected to the plurality of light-emitting elements,
wherein each of the plurality of pixel drivers comprises:
a first transistor comprising a first oxide semiconductor pattern having a crystalline structure;
a second transistor electrically connected to the first transistor and comprising a second oxide semiconductor pattern having an amorphous structure; and
a capacitor that is electrically connected to a gate of the first transistor.

2. The display panel of claim 1, wherein the first transistor is a driving transistor and the second transistor is a switching transistor.

3. The display panel of claim 1, wherein the first oxide semiconductor pattern comprises at least one of indium, gallium, or zinc.

4. The display panel of claim 1, wherein the second oxide semiconductor pattern comprises at least one of indium, tin, gallium, or zinc.

5. The display panel of claim 1, wherein the second oxide semiconductor pattern comprises indium, tin, gallium and zinc, and
wherein a composition ratio in the second semiconductor oxide pattern is about 60 to about 80 wt % of indium, about 0.5 to about 8 wt % of tin, about 5 to about 15 wt % of gallium, and about 10 to about 30 wt % of zinc.

6. The display panel of claim 1, wherein the first oxide semiconductor pattern and the second oxide semiconductor pattern are disposed on a same layer.

7. The display panel of claim 6, further comprising:
a lower conductive layer disposed between the first transistor and the substrate; and
a buffer layer disposed between the lower conductive layer and the first oxide semiconductor pattern,
wherein the first oxide semiconductor pattern and the second oxide semiconductor pattern are disposed on the buffer layer.

8. The display panel of claim 7, wherein a source of the first transistor is electrically connected to the lower conductive layer.

9. The display panel of claim 1, wherein each of the first transistor and the second transistor has a top-gate structure.

10. An electronic device, comprising:
a display module;
a processor electrically operating the display module, and wherein the display module comprises:
a substrate;
a light-emitting element disposed on the substrate;
a driving transistor disposed on the substrate and electrically connected to the light-emitting element; and
a plurality of switching transistors electrically connected to the driving transistor and the light-emitting element,
wherein the driving transistor comprises a first oxide semiconductor pattern with a crystalline structure, and
wherein each of the plurality of switching transistors comprises a second oxide semiconductor pattern with an amorphous structure.

11. The electronic device of claim 10, wherein the driving transistor and each of the plurality of switching transistors has a top-gate structure.

12. The electronic device of claim 11, wherein the first oxide semiconductor pattern and the second oxide semiconductor pattern are disposed on a same layer.

13. The electronic device of claim 12, wherein a source electrode and a drain electrode of each of the driving transistor and switching transistors are disposed on a same layer.

14. The electronic device of claim 12, further comprising:
a buffer layer disposed between the substrate and the driving transistor; and
a lower conductive layer disposed between the buffer layer and the substrate and overlapping the first oxide semiconductor pattern,
wherein a source of the driving transistor contacts the lower conductive layer.

15. The electronic device of claim 10, wherein the first oxide semiconductor pattern has a charge mobility of about 30 cm²/v·s or higher.

16. The electronic device of claim 10, wherein the second oxide semiconductor pattern has a driving range of about 0.4 V or higher.

17. A method of manufacturing a display panel, comprising:
disposing a first thin-film transistor on a substrate, the first thin-film transistor comprising a first semiconductor pattern;
disposing a second thin-film transistor on the substrate, the second thin-film transistor comprising a second semiconductor pattern that is spaced apart from the first semiconductor pattern; and
disposing a light-emitting element on the substrate,
wherein the disposing of the first thin-film transistor on the substrate comprises:
providing a first semiconductor layer with a first oxide semiconductor material;
patterning the first semiconductor layer to provide the first semiconductor pattern; and
crystallizing the first semiconductor pattern,
wherein the providing of the second thin-film transistor comprises:
disposing a second semiconductor layer with a second semiconductor material on the first semiconductor pattern; and
patterning the second semiconductor layer to provide the second semiconductor pattern,
wherein the second semiconductor pattern has an amorphous structure.

18. The method of claim 17, wherein the second semiconductor layer contacts the first semiconductor pattern.

19. The method of claim 18, wherein the patterning of the second semiconductor layer comprises using an enchant to etch the second semiconductor layer,
wherein the first semiconductor pattern is exposed to the enchant.

20. The method of claim 17, wherein a source, a drain and a channel of each of the first semiconductor pattern and the second semiconductor pattern are provided substantially simultaneously.
